(19) United States
(12) Patent Application Publication
(10) Pub. No.: US 2010/0157533 A1
(43) Pub. Date: Jun. 24, 2010

(54) HEAT-TRANSPORTING DEVICE, ELECTRONIC APPARATUS, AND METHOD OF PRODUCING A HEAT-TRANSPORTING DEVICE

(75) Inventors: Kazunao Oniki, Tokyo (JP); Takashi Yajima, Tokyo (JP); Kazuo Goto, Kanagawa (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: SONY CORPORATION, Tokyo (JP)

(21) Appl. No.: 12/633,958

(22) Filed: Dec. 9, 2009

(30) Foreign Application Priority Data
Dec. 24, 2008 (JP) 2008-328870

(51) Int. Cl. H05K 7/20; F28D 15/02; B21D 53/02

(52) U.S. Cl. 361/700; 165/104.26; 29/890.032

(57) ABSTRACT

A heat-transporting device includes a working fluid, a vessel, a vapor-phase flow path, and a liquid-phase flow path. The working fluid transports heat using a phase change. The vessel seals in the working fluid. The vapor-phase flow path causes the working fluid in a vapor phase to circulate inside the vessel. The liquid-phase flow path includes a laminated body and causes the working fluid in a liquid phase to circulate inside the vessel, the laminated body including a first mesh member and a second mesh member and being formed such that the first mesh member and the second mesh member are laminated while weaving directions thereof differ relatively.

### BACKGROUND OF THE INVENTION

1. Field of the Invention

The present invention relates to a heat-transporting device for transporting heat using a phase change of a working fluid, an electronic apparatus including the heat-transporting device, and a method of producing a heat-transporting device.

2. Description of the Related Art

From the past, a heat pipe has been widely used as a device for transporting heat from a heat source such as a CPU (Central Processing Unit) of a PC (Personal Computer). As the heat pipe, a pipe heat pipe and a planar heat pipe are widely known. In such a heat pipe, a working fluid such as water is sealed inside and circulated while changing phases inside the heat pipe, to thus transport heat from a heat source such as a CPU. A driving source for circulating a working fluid needs to be provided inside the heat pipe, and a metal sintered body, a metal mesh, and the like for generating a capillary force are generally used.

For example, Japanese Patent Application Laid-open No. 2006-292355 (paragraphs (0003), (0010), and (0011), FIGS. 1, 3, and 4) discloses a heat pipe that uses a metal sintered body or a metal mesh.

### SUMMARY OF THE INVENTION

However, the heat pipe that transports heat using a capillary force of a metal mesh has had a problem that it is difficult to enhance heat-transporting performance.

For example, mesh members may be laminated for enhancing heat-transporting performance. In this case, because the mesh members overlap each other, an appropriate space cannot be secured between the mesh members, with the result that a flow path resistance increases and a capillary force is lowered. Therefore, it has been difficult to enhance heat-transporting performance, which is problematic.

In view of the circumstances as described above, there is a need for a heat-transporting device that has high heat-transporting performance, an electronic apparatus including the heat-transporting device, and a method of producing a heat-transporting device.

According to an embodiment of the present invention, there is provided a heat-transporting device including a working fluid, a vessel, a vapor-phase flow path, and a liquid-phase flow path.

The working fluid transports heat using a phase change.

The vessel seals in the working fluid.

The vapor-phase flow path causes the working fluid in a vapor phase to circulate inside the vessel.

The liquid-phase flow path includes a laminated body and causes the working fluid in a liquid phase to circulate inside the vessel.

The laminated body includes a first mesh member and a second mesh member and is formed such that the first mesh member and the second mesh member are laminated while weaving directions thereof differ relatively.

The “weaving directions” of the mesh members are directions in which first wires and second wires that form the mesh member are woven.

In the embodiment of the present invention, the laminated body that constitutes the liquid-phase flow path is formed by laminating the first mesh member and the second mesh member while relatively differentiating weaving directions thereof. With this structure, an adequate space can be formed between the first mesh member and the second mesh member. Accordingly, a low flow-path resistance and a high capillary force can be realized, with the result that heat-transporting performance of the heat-transporting device can be improved.

In the heat-transporting device, at least one of the first mesh member and the second mesh member may include a plurality of first wires and a plurality of second wires.

The plurality of first wires are arranged at first intervals.

The plurality of second wires are woven into the plurality of first wires and arranged at second intervals different from the first intervals.

In the embodiment of the present invention, the intervals of the plurality of first wires and second wires that constitute the mesh member differ. For example, assuming a case where the plurality of first wires are arranged such that each of the plurality of first wires extends in a direction along the liquid-phase flow path, by forming the intervals of the second wires (second intervals) to be wider than the intervals of the first wires (first intervals), a flow-path resistance can be reduced. Thus, a capillary force of the mesh member can be enhanced, with the result that heat-transporting performance can be improved.

In the heat-transporting device, the first mesh member may have a first mesh number.

In this case, the second mesh member may have a second mesh number different from the first mesh number.

The “mesh number” refers to the number of meshes of a mesh member per inch (25.4 mm).

In the embodiment of the present invention, the mesh number of the first mesh member and the mesh number of the second mesh member differ. With this structure, an effect of preventing the laminated mesh members from overlapping each other is enhanced additionally. As a result, heat-transporting performance of the heat-transporting device can be additionally improved.

In the heat-transporting device, a relative angle of the weaving directions of the first mesh member and the second mesh member may range from 5 degrees to 85 degrees.

As long as the relative angle of the weaving directions ranges from 5 degrees to 85 degrees as described above, the mesh members can appropriately be prevented from overlapping each other, and heat-transporting performance of the heat-transporting device can be improved.

In the heat-transporting device, the vapor-phase flow path may include a third mesh member.

In the embodiment of the present invention, the vapor-phase flow path is constituted of a mesh member. With this structure, durability of the heat-transporting device can be improved. For example, it is possible to prevent the vessel from being deformed by an internal pressure when heat is applied to the heat-transporting device. Moreover, durability of the heat-transporting device in a case where the device is subjected to a bending process can be improved.

In the heat-transporting device, the vessel may be plate-like.

In the heat-transporting device, the vessel may be formed by bending a plate member so that the laminated body is sandwiched by the bent plate member.

With this structure, since the vessel can be formed of a single plate member, costs can be reduced.

According to another embodiment of the present invention, there is provided a heat-transporting device including a working fluid, a vessel, a vapor-phase flow path, and a liquid-phase flow path.

The working fluid transports heat using a phase change.

The vessel seals in the working fluid.

The vapor-phase flow path causes the working fluid in a vapor phase to circulate inside the vessel.

The liquid-phase flow path includes a first mesh member and causes the working fluid in a liquid phase to circulate inside the vessel.

The first mesh member includes a plurality of first wires and a plurality of second wires.

The plurality of first wires are arranged at first intervals.

The plurality of second wires are woven into the plurality of first wires and arranged at second intervals different from the first intervals.

In the embodiment of the present invention, the intervals of the plurality of first wires and second wires that constitute the first mesh member differ. For example, assuming a case where the plurality of first wires are arranged such that each of the plurality of first wires extends in a direction along the liquid-phase flow path, by forming the intervals of the second wires (second intervals) to be wider than the intervals of the first wires (first intervals), a flow-path resistance of the liquid-phase flow path can be reduced. Thus, a capillary force of the first mesh member can be enhanced, with the result that heat-transporting performance can be improved.

In the heat-transporting device, the vapor-phase flow path may include a second mesh member.

In this case, the second mesh member may include a plurality of third wires and a plurality of fourth wires.

The plurality of third wires are arranged at third intervals.

The plurality of fourth wires are woven into the plurality of third wires and arranged at fourth intervals different from the third intervals.

For example, assuming a case where the plurality of third wires are arranged such that each of the plurality of third wires extends in a direction along the vapor-phase flow path, by forming the intervals of the fourth wires (fourth intervals) to be wider than the intervals of the third wires (third intervals), a flow-path resistance of the vapor-phase flow path can be reduced. Thus, heat-transporting performance of the heat-transporting device can be improved. In addition, since the vapor-phase flow path is constituted of a mesh member in the embodiment of the present invention, durability of the heat-transporting device can be improved as compared to a case where the vapor-phase flow path is hollow.

In the heat-transporting device, the plurality of first wires may be arranged such that each of the plurality of first wires extends in a direction along the liquid-phase flow path.

In this case, the plurality of second wires may be arranged such that each of the plurality of second wires extends in a direction orthogonal to the direction along the liquid-phase flow path.

Moreover, in this case, the second intervals may be wider than the first intervals.

In the embodiment of the present invention, the intervals of the second wires extending in the direction orthogonal to the liquid-phase flow path (second intervals) are formed to be wider than the intervals of the first wires extending in the direction along the liquid-phase flow path (first intervals). With this structure, a capillary force of the first mesh member can be enhanced as described above, with the result that heat-transporting performance of the heat-transporting device can be improved.

In the heat-transporting device, the plurality of third wires may be arranged such that each of the plurality of third wires extends in a direction along the vapor-phase flow path.

In this case, the plurality of fourth wires may be arranged such that each of the plurality of fourth wires extends in a direction orthogonal to the direction along the vapor-phase flow path.

Moreover, in this case, the fourth intervals may be wider than the third intervals.

In the embodiment of the present invention, the intervals of the fourth wires extending in the direction orthogonal to the vapor-phase flow path (fourth intervals) are formed to be wider than the intervals of the third wires extending in the direction along the vapor-phase flow path (third intervals). With this structure, a flow-path resistance of the vapor-phase flow path can be reduced as described above, with the result that heat-transporting performance of the heat-transporting device can be improved.

According to another embodiment of the present invention, there is provided a heat-transporting device including a working fluid, a vessel, a vapor-phase flow path, and a liquid-phase flow path.

The working fluid transports heat using a phase change.

The vessel seals in the working fluid.

The vapor-phase flow path causes the working fluid in a vapor phase to circulate inside the vessel.

The liquid-phase flow path includes a first mesh member and a second mesh member and causes the working fluid in a liquid phase to circulate inside the vessel.

The first mesh member has a first mesh number.

The second mesh member is laminated on the first mesh member and has a second mesh number different from the first mesh number.

In the embodiment of the present invention, the mesh number of the first mesh member and the mesh number of the second mesh member differ. With this structure, it is possible to prevent the mesh members from overlapping each other, and a low flow-path resistance and a high capillary force can therefore be realized. As a result, heat-transporting performance of the heat-transporting device can be improved.

In the heat-transporting device, the first mesh number and the second mesh number may be set so that a periodicity of the first mesh member and that of the second mesh member differ.

A case where the “periodicity of the first mesh member and that of the second mesh member differ” refers to a case where the first mesh number is, for example, ⅔, ¾, ⅘, 4 times, or 5 times the second mesh number. Conversely, a case where the periodicity of the first mesh member and that of the second mesh member coincide refers to a case where the second mesh number is, for example, ½, ⅓, twice, or 3 times the first mesh number.

For example, since the periodicities of the mesh members coincide when the first mesh number is ½, ⅓, twice, or 3 times the second mesh number, the mesh members may overlap each other. Since it is possible to prevent the periodicity of the first mesh member and that of the second mesh member from coinciding in the embodiment of the present invention, an overlap of the mesh members can appropriately be prevented.

In the heat-transporting device, the vapor-phase flow path may include a third mesh member.

Since the vapor-phase flow path is constituted of a mesh member in the embodiment of the present invention, durability of the heat-transporting device can be improved as compared to a case where the vapor-phase flow path is hollow.

According to an embodiment of the present invention, there is provided an electronic apparatus including a heat source and a heat-transporting device.

The heat-transporting device includes a working fluid, a vessel, a vapor-phase flow path, and a liquid-phase flow path.

The working fluid transports heat of the heat source using a phase change.

The vessel seals in the working fluid.

The vapor-phase flow path causes the working fluid in a vapor phase to circulate inside the vessel.

The liquid-phase flow path includes a laminated body and causes the working fluid in a liquid phase to circulate inside the vessel.

The laminated body includes a first mesh member and a second mesh member and is formed such that the first mesh member and the second mesh member are laminated while weaving directions thereof differ relatively.

According to another embodiment of the present invention, there is provided an electronic apparatus including a heat source and a heat-transporting device.

The heat-transporting device includes a working fluid, a vessel, a vapor-phase flow path, and a liquid-phase flow path.

The working fluid transports heat of the heat source using a phase change.

The vessel seals in the working fluid.

The vapor-phase flow path causes the working fluid in a vapor phase to circulate inside the vessel.

The liquid-phase flow path includes a mesh member and causes the working fluid in a liquid phase to circulate inside the vessel.

The mesh member includes a plurality of first wires and a plurality of second wires.

The plurality of first wires are arranged at first intervals.

The plurality of second wires are woven into the plurality of first wires and arranged at second intervals different from the first intervals.

According to another embodiment of the present invention, there is provided an electronic apparatus including a heat source and a heat-transporting device.

The heat-transporting device includes a working fluid, a vessel, a vapor-phase flow path, and a liquid-phase flow path.

The working fluid transports heat of the heat source using a phase change.

The vessel seals in the working fluid.

The vapor-phase flow path causes the working fluid in a vapor phase to circulate inside the vessel.

The liquid-phase flow path includes a first mesh member and a second mesh member and causes the working fluid in a liquid phase to circulate inside the vessel.

The first mesh member has a first mesh number.

The second mesh member is laminated on the first mesh member and has a second mesh number different from the first mesh number.

According to an embodiment of the present invention, there is provided a method of producing a heat-transporting device, including bending a plate member such that a capillary member that causes a capillary force to act on a working fluid that transports heat using a phase change is sandwiched by the bent plate member.

The bent plate member is bonded.

As a result, since a vessel can be formed by a single plate member, costs can be reduced.

As described above, according to the embodiments of the present invention, a heat-transporting device that has high heat-transporting performance, an electronic apparatus including the heat-transporting device, and a method of producing a heat-transporting device can be provided.

These and other objects, features and advantages of the present invention will become more apparent in light of the following detailed description of best mode embodiments thereof, as illustrated in the accompanying drawings.

### BRIEF DESCRIPTION OF DRAWINGS

FIG. 1 is a perspective view of a heat-transporting device according to an embodiment of the present invention;

FIG. 2 is a cross-sectional side view of the heat-transporting device taken along the line A-A of FIG. 1;

FIG. 3 are plan views of an upper-layer mesh member and a lower-layer mesh member, respectively;

FIG. 4 are enlarged plan views of the upper-layer mesh member and the lower-layer mesh member, respectively;

FIG. 5 are each an enlarged cross-sectional diagram of a laminated body;

FIG. 6 is a schematic diagram for explaining an operation of the heat-transporting device;

FIG. 7 is a diagram showing a relationship between a relative angle of weaving directions of the upper-layer mesh member and lower-layer mesh member and heat-transporting performance of the heat-transporting device;

FIG. 8 is a cross-sectional side view of a heat-transporting device according to another embodiment of the present invention;

FIG. 9 are each a plan view of a mesh member;

FIG. 10 is a perspective view of a heat-transporting device according to another embodiment of the present invention;

FIG. 11 is a cross-sectional diagram taken along the line A-A of FIG. 10;

FIG. 12 is a cross-sectional side view of a heat-transporting device according to another embodiment of the present invention;

FIG. 13 is a cross-sectional side view of a heat-transporting device according to another embodiment of the present invention;

FIG. 14 is an enlarged plan view of a mesh member;

FIG. 15 is a diagram for explaining heat-transporting performance of the heat-transporting device, the diagram showing a relationship between open stitches in y- and x-axis directions and a maximum heat-transporting amount Qmax;

FIG. 16 is a diagram showing a relationship between open stitches of a vapor-phase mesh member in y- and x-axis directions and the maximum heat-transporting amount Qmax;

FIG. 17 is a cross-sectional side view of a heat-transporting device according to another embodiment of the present invention;

FIG. 18 are each an enlarged cross-sectional diagram of a laminated body;

FIG. 19 is a diagram showing a relationship between mesh numbers of adjacent mesh members and heat-transporting performance of the heat-transporting device;

FIG. 20 are enlarged cross-sectional diagrams of a laminated body for explaining an overlap of the mesh members due to periodicities thereof;

FIG. 21 is a diagram obtained as a result of comparing heat-transporting performance of heat-transporting devices respectively including the laminated bodies shown in FIG. 20;

FIG. 22 is a perspective view of a heat-transporting device according to another embodiment of the present invention;

FIG. 23 is a cross-sectional diagram taken along the line A-A of FIG. 22;

FIG. 24 is a development view of a plate member that constitutes a vessel of the heat-transporting device according to the embodiment;

FIG. 25 are diagrams showing a method of producing a heat-transporting device according to another embodiment of the present invention;

FIG. 26 is a development view of a plate member for explaining a heat-transporting device according to a modified example;

FIG. 27 is a perspective view of a heat-transporting device according to another embodiment of the present invention;

FIG. 28 is a cross-sectional diagram taken along the line A-A of FIG. 27;

FIG. 29 is a development view of a plate member that constitutes a vessel of the heat-transporting device according to the embodiment;

FIG. 30 is a perspective view of a laptop PC; and

FIG. 31 is a diagram showing a heat-transporting device in which a heat source is disposed on a vapor-phase flow path side.

### DESCRIPTION OF PREFERRED EMBODIMENTS

Hereinafter, embodiments of the present invention will be described with reference to the drawings.

### First Embodiment

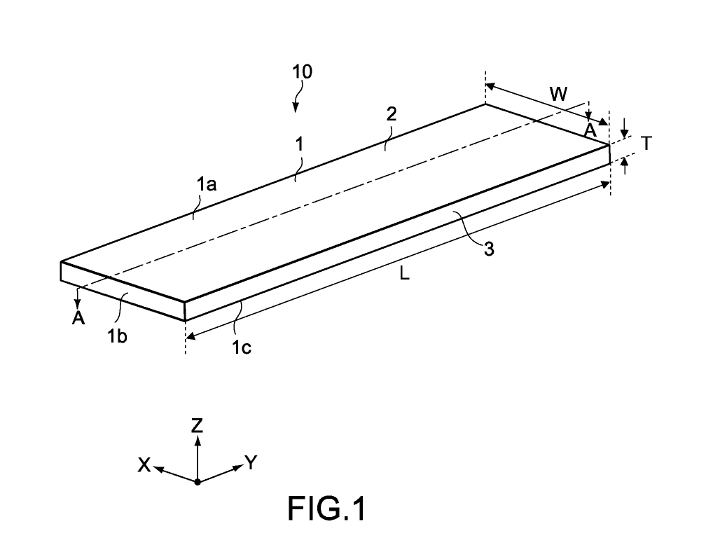

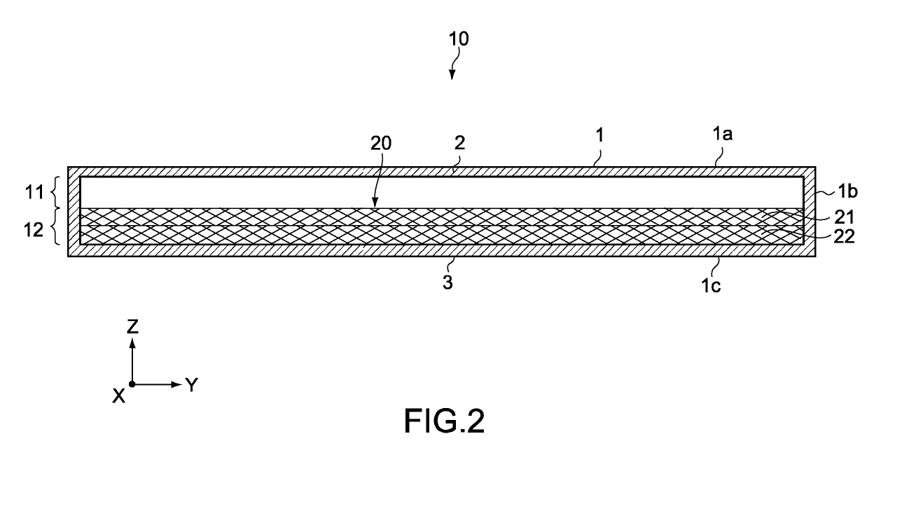

FIG. 1 is a perspective view of a heat-transporting device according to a first embodiment. FIG. 2 is a cross-sectional side view of the heat-transporting device taken along the line A-A of FIG. 1. It should be noted that in the specification, for brevity of descriptions on the figures, a heat-transporting device, components of the heat-transporting device, and the like may be illustrated in sizes different from actual sizes thereof.

As shown in the figures, a heat-transporting device 10 includes a thin rectangular plate-like vessel 1 that is elongated in one direction (y-axis direction). The vessel 1 is formed by bonding an upper plate member 2 that constitutes an upper portion 1a of the vessel 1 and a lower plate member 3 that constitutes a circumferential side portion 1b and a lower portion 1c of the vessel 1. A concave portion is formed in the lower plate member 3, and the concave portion forms a space inside the vessel 1.

Typically, the upper plate member 2 and the lower plate member 3 are made of oxygen-free copper, tough pitch copper, or a copper alloy. However, the materials are not limited thereto, and the upper plate member 2 and the lower plate member 3 may be made of metal other than copper, or a material having high heat conductivity may be used instead.

As a method of bonding the upper plate member 2 and the lower plate member 3, there are a diffusion bonding method, an ultrasonic bonding method, a brazing method, a welding method, and the like.

A length L of the vessel 1 (y-axis direction) is, for example, 10 mm to 500 mm, and a width W of the vessel 1 (x-axis direction) is, for example, 5 mm to 300 mm. Moreover, a thickness T of the vessel 1 (z-axis direction) is, for example, 0.3 mm to 5 mm. The length L, width W, and thickness T of the vessel 1 are not limited to those values and may of course take other values.

An inlet (not shown) that has a diameter of about 0.1 mm to 1 mm, for example, is provided in the vessel 1, and a working fluid is injected into the vessel 1 through this inlet. The working fluid is typically injected in a state where the vessel 1 is pressure-reduced inside.

Examples of the working fluid include pure water, alcohol such as ethanol, fluorine-based liquid such as Fluorinert FC72, and a mixture of pure water and alcohol.

As shown in FIG. 2, the vessel 1 of the heat-transporting device 10 is hollow inside on the upper portion 1a side, and a laminated body 20 is disposed on the lower portion 1c side. The laminated body 20 is formed by laminating two mesh members 21 and 22. By the cavity formed inside the heat-transporting device 10, a vapor-phase flow path 11 that causes the working fluid in a vapor phase to circulate is formed. Moreover, by the laminated body 20 disposed inside the heat-transporting device 10, a liquid-phase flow path 12 that causes the working fluid in a liquid phase to circulate is formed.

In descriptions below, the mesh member 21 as an upper layer out of the two laminated mesh members 21 and 22 will be referred to as upper-layer mesh member 21, whereas the mesh member 22 as a lower layer out of those two members will be referred to as lower-layer mesh member 22.

The upper-layer mesh member 21 and the lower-layer mesh member 22 are each made of, for example, copper, phosphor bronze, aluminum, silver, stainless steel, molybdenum, or an alloy thereof.

The upper-layer mesh member 21 and the lower-layer mesh member 22 are typically formed by cutting out a mesh member having a large area into arbitrary sizes.

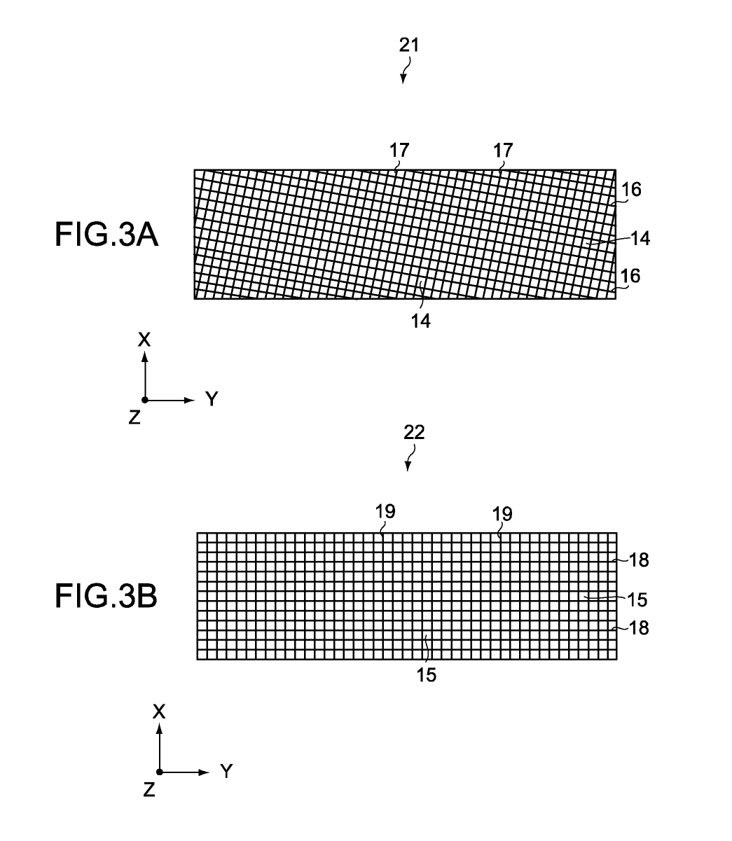

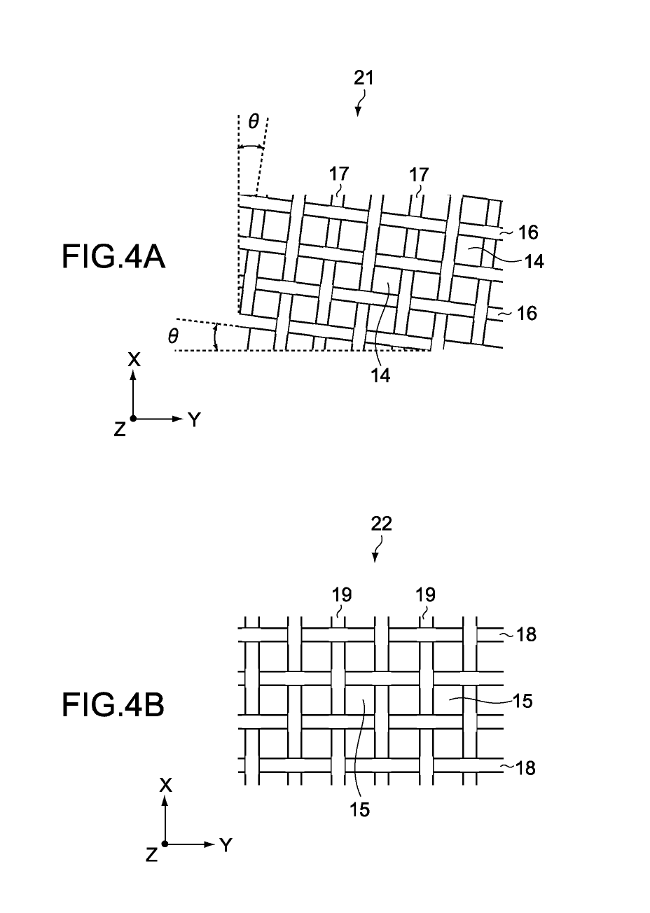

FIG. 3 are plan views of the upper-layer mesh member and the lower-layer mesh member, respectively. FIG. 4 are enlarged plan views of the upper-layer mesh member and the lower-layer mesh member, respectively.

As shown in FIGS. 3A and 4A, the upper-layer mesh member 21 is formed by weaving a plurality of first wires 16 and a plurality of second wires 17 in mutually-orthogonal directions.

As shown in FIGS. 3B and 4B, the lower-layer mesh member 22 is also formed by weaving a plurality of third wires 18 and a plurality of fourth wires 19 in mutually-orthogonal directions.

As a way to weave the wires to obtain the upper-layer mesh member 21 and the lower-layer mesh member 22, there are, for example, plain weave and twilling. However, the present invention is not limited thereto, and lock crimp weave, flat-top weave, or other weaving methods may also be used.

A plurality of holes 14 are formed by spaces defined by the first wires 16 and the second wires 17. Similarly, a plurality of holes 15 are formed by spaces defined by the third wires 18 and the fourth wires 19. In the specification, holes formed by wires like the holes 14 and 15 may be referred to as meshes.

The first wires 16 of the upper-layer mesh member 21 extend in a direction that is tilted a predetermined angle θ with respect to the y-axis direction. In this case, since the second wires 17 are woven in a direction orthogonal to the first wires 16, the second wires 17 extend in a direction that is tilted a predetermined angle θ with respect to the x-axis direction.

On the other hand, the third wires 18 of the lower-layer mesh member 22 extend in the y-axis direction. In this case, the fourth wires 19 extend in the x-axis direction.

In descriptions below, directions in which the first wires 16 and the second wires 17 extend, that is, directions in which the first and second wires are woven will be referred to as weaving directions of the upper-layer mesh member 21. Similarly, directions in which the third wires 18 and the fourth wires 19 are woven will be referred to as weaving directions of the lower-layer mesh member 22.

Specifically, the weaving directions of the upper-layer mesh member 21 are directions that are tilted a predetermined angle θ with respect to the y- and x-axis directions, and the weaving directions of the lower-layer mesh member 22 are directions along the y- and x-axis directions. Thus, in the heat-transporting device 10 of this embodiment, the weaving directions of the upper-layer mesh member 21 and the weaving directions of the lower-layer mesh member 22 differ relatively.

As described above, the upper-layer mesh member 21 and the lower-layer mesh member 22 are typically formed by cutting out a mesh member having a large area into arbitrary sizes. Therefore, it is relatively easy to form the mesh member 21 that has weaving directions in directions that are tilted a predetermined angle θ with respect to the y- and x-axis directions as shown in FIGS. 3A and 4A.

FIG. 3 show an exemplary case where the weaving directions of meshes of the upper-layer mesh member 21 are directions that are tilted a predetermined angle θ with respect to the y- and x-axis directions and the weaving directions of meshes of the lower-layer mesh member 22 are the y- and x-axis directions. However, the weaving directions of the upper-layer mesh member 21 and the lower-layer mesh member 22 are not limited thereto.

Typically, the weaving directions of the upper-layer mesh member 21 and the weaving directions of the lower-layer mesh member 22 only need to differ relatively. For example, the weaving directions of the upper-layer mesh member 21 may be the y- and x-axis directions and the weaving directions of the lower-layer mesh member 22 may be directions that are tilted a predetermined angle θ with respect to the y- and x-axis directions.

It should be noted that a relative angle of the weaving directions of the upper-layer mesh member 21 and the weaving directions of the lower-layer mesh member 22 will be described later in detail.

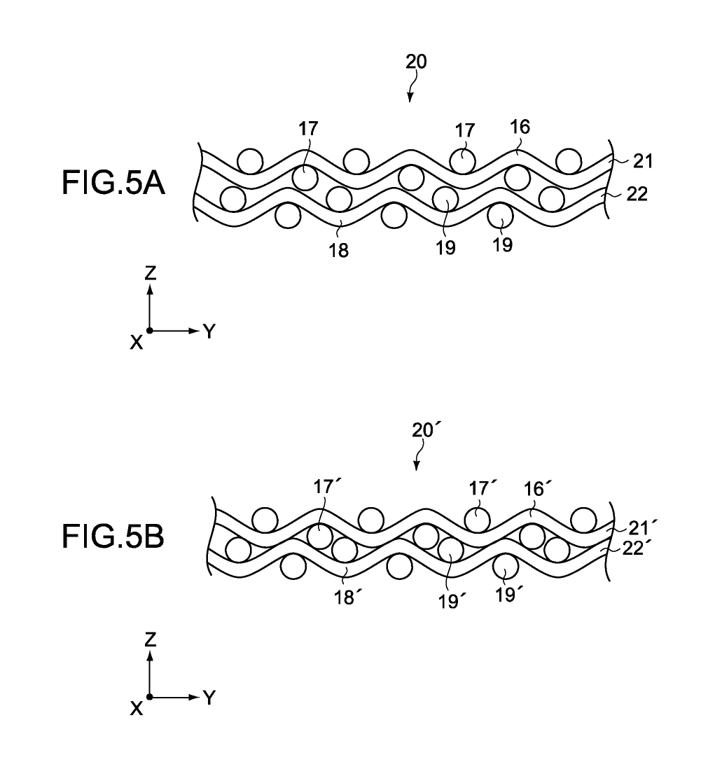

FIG. 5 are each an enlarged cross-sectional diagram of a laminated body. FIG. 5A is an enlarged cross-sectional diagram of the laminated body 20, and FIG. 5B is an enlarged cross-sectional diagram of a laminated body 20′ according to a comparative example.

First, the laminated body 20′ of the comparative example will be described with reference to FIG. 5B. The laminated body 20′ of the comparative example includes an upper-layer mesh member 21′ including first wires 16′ and second wires 17′ and a lower-layer mesh member 22′ including third wires 18′ and fourth wires 19′.

The upper-layer mesh member 21′ and the lower-layer mesh member 22′ each have weaving directions in the y- and x-axis directions. In other words, the laminated body 20′ is formed by laminating the upper-layer mesh member 21′ and the lower-layer mesh member 22′ that have the same weaving directions.

As shown in FIG. 5B, when the mesh members 21′ and 22′ that have the same weaving directions are laminated to form the laminated body 20′, the mesh members 21′ and 22′ overlap each other.

As a result, a space to seal in a working fluid in a liquid phase becomes too small in the laminated body 20′, thus increasing a flow-path resistance of the liquid-phase working fluid. In addition, the laminated body 20′cannot fully exert a capillary force.

On the other hand, by relatively differentiating the weaving directions of the upper-layer mesh member 21 and the weaving directions of the lower-layer mesh member 22 as shown in FIG. 5A, the mesh members 21 and 22 can be prevented from overlapping each other. Thus, since a sufficient flow path for causing the liquid-phase working fluid to circulate can be secured, a flow-path resistance of the liquid-phase working fluid can be reduced and a high capillary force can be generated. As a result, heat-transporting performance of the heat-transporting device 10 can be improved.

(Description on Operation)

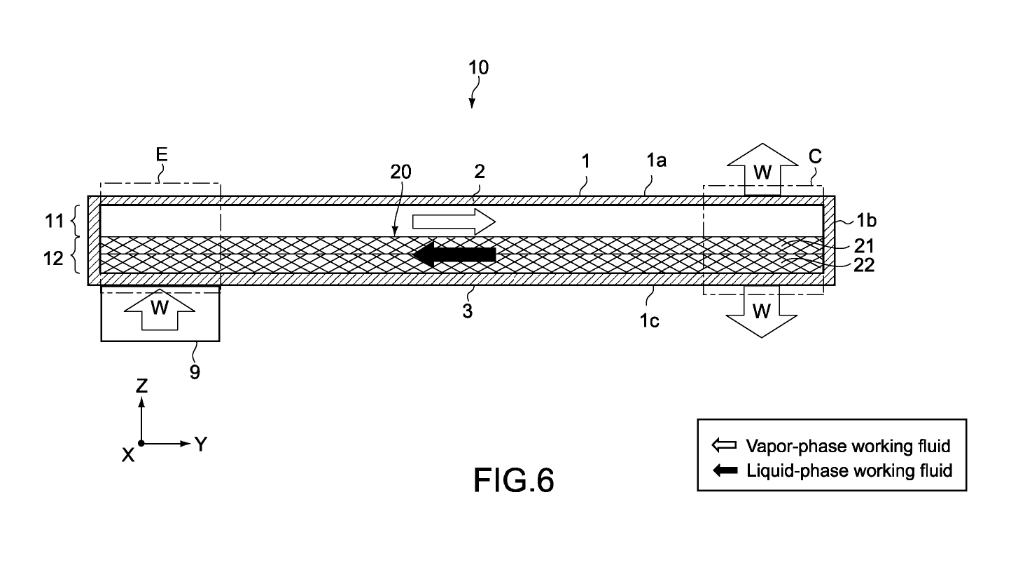

Next, an operation of the heat-transporting device 10 will be described. FIG. 6 is a schematic diagram for explaining an operation of the heat-transporting device.

As shown in FIG. 6, the heat-transporting device 10 is in contact with, at one end portion thereof on the lower portion 1c side, a heat source 9 such as a CPU. The heat-transporting device 10 includes an evaporation area E at an end portion thereof on a side that is in contact with the heat source 9 and a condensation area C at the other end portion thereof. The liquid-phase working fluid absorbs heat W from the heat source 9 such as a CPU in the evaporation area E, changes its own phase from the liquid-phase working fluid to the vapor-phase working fluid, and moves on to the vapor-phase flow path 11 from the liquid-phase flow path 12, for example. The vapor-phase working fluid moves inside the vapor-phase flow path 11 toward the condensation area C from the evaporation area E and radiates the heat W in the condensation area C. Upon radiating the heat W in the condensation area C, the vapor-phase working fluid changes its own phase from the vapor-phase working fluid to the liquid-phase working fluid, and moves toward the evaporation area E from the condensation area C using a capillary force of the laminated body 20. The liquid-phase working fluid that has reached the evaporation area E by the capillary force of the laminated body 20 again absorbs heat W from the heat source 9 such as a CPU and moves to the vapor-phase flow path 11 from the liquid-phase flow path 12. By the phase change of the working fluid as described above, the heat-transporting device 10 can transport the heat W of the heat source 9 such as a CPU. It should be noted that a heat-radiating member such as a heatsink may be provided on the condensation area C side.

Here, since the laminated body 20 constituting the liquid-phase flow path is formed by laminating the upper-layer mesh member 21 and the lower-layer mesh member 22 that have relatively-different weaving directions as described above, the laminated body 20 has a low flow-path resistance and a high capillary force. Therefore, the laminated body 20 is capable of causing the liquid-phase working fluid to circulate with a powerful pumping force. Accordingly, an improvement of heat-transporting performance is realized in the heat-transporting device 10 of this embodiment.

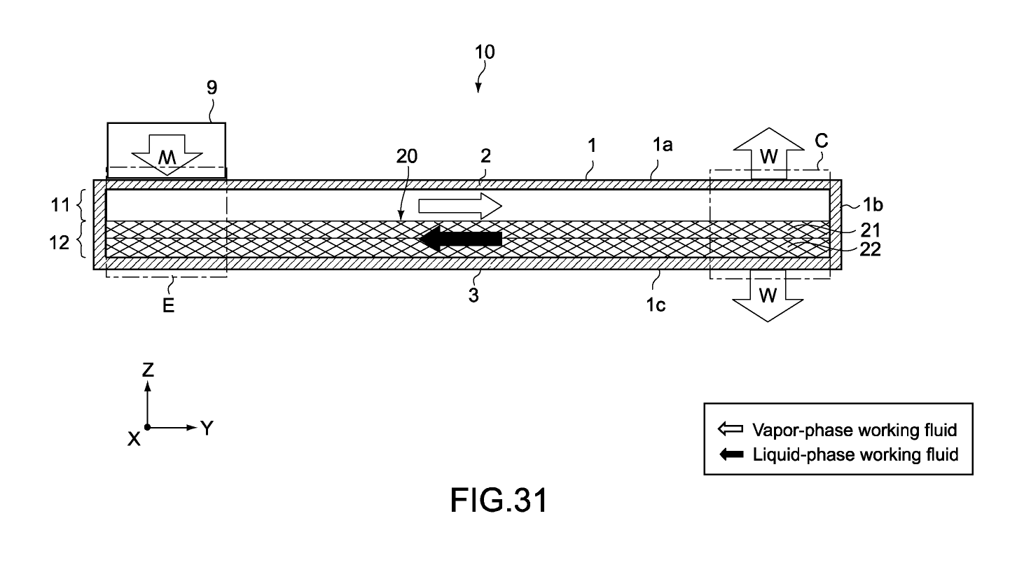

In the description on FIG. 6, a position at which the heat-transporting device 10 comes into contact with the heat source 9 such as a CPU has been on the lower portion 1c side, that is, the liquid-phase flow path 12 side. However, the position that is in contact with the heat source 9 may be on the vapor-phase flow path 11 side. In this case, the heat source 9 is disposed so as to come into contact with one end portion of the heat-transporting device 10 on the upper portion 1a side. Alternatively, the heat source 9 may be disposed so as to come into contact with both the liquid-phase flow path 12 side and the vapor-phase flow path 11 side of the heat-transporting device 10. In other words, since the heat-transporting device 10 of this embodiment is like a thin plate, it can exert high heat-transporting performance irrespective of the position that is in contact with the heat source 9. It should be noted that for reference, the heat-transporting device 10 in which the heat source 9 is disposed on the vapor-phase flow path 11 side is shown in FIG. 31.

(Relationship Between Relative Angle of Weaving Directions and Heat-Transporting Performance)

Next, a relationship between a relative angle of weaving directions of the upper-layer mesh member 21 and the lower-layer mesh member 22 that are adjacent to each other and heat-transporting performance of the heat-transporting device will be described.

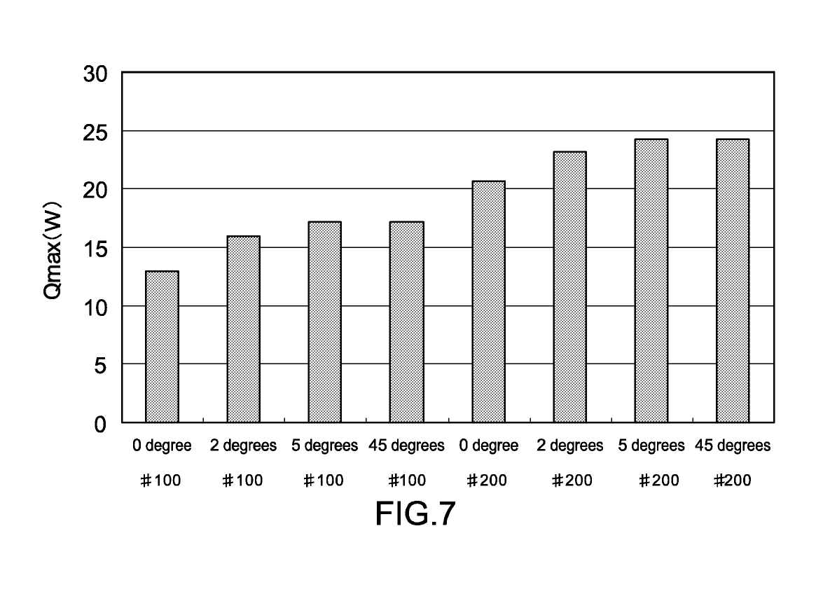

FIG. 7 is a diagram showing the relationship between the relative angle of the weaving directions of the upper-layer mesh member 21 and the lower-layer mesh member 22 and the heat-transporting performance of the heat-transporting device.

For examining the relationship, a plurality of mesh members whose weaving directions in the y- and x-axis directions differ in the angle θ (0 degree, 2 degrees, 5 degrees, and 45 degrees) were prepared. Those mesh members were each laminated on the lower-layer mesh member 22 as the upper-layer mesh member 21, to thus evaluate the relationship. The lower-layer mesh member 22 was disposed inside the vessel 1 such that weaving directions thereof were in the y- and x-axis directions.

Further, as the upper-layer mesh member 21 and the lower-layer mesh member 22, a mesh member with a mesh number 100 and a mesh member with a mesh number 200 were prepared. The mesh number used herein refers to the number of meshes 14 and 15 of the mesh member per inch (25.4 mm).

In descriptions below, in a case where a mesh number of a mesh member is abc, that mesh number may be represented as #abc. For example, the mesh number 100 is represented as #100.

In FIG. 7, the abscissa axis represents a relative angle of weaving directions and a mesh number, and the ordinate axis represents a maximum heat-transporting amount Qmax of the heat-transporting device 10.

As shown in FIG. 7, the maximum heat-transporting amount Qmax is larger when the relative angle of weaving directions is 2 to 45 degrees than when the relative angle of weaving directions is 0 degree. It can be seen from the result that by forming the liquid-phase flow path 12 by laminating mesh members having relatively-different weaving directions, the maximum heat-transporting amount Qmax of the heat-transporting device 10 increases, that is, heat-transporting performance is improved. The maximum heat-transporting amount Qmax increases also when mesh members 21 and 22 having a mesh number #100 are used and also when mesh members 21 and 22 having a mesh number #200 are used.

It can also be seen from FIG. 7 that the maximum heat-transporting amount Qmax is larger when the relative angle of weaving directions is 5 degrees than when it is 2 degrees. In addition, it can be seen that the maximum heat-transporting amount Qmax is substantially the same at times the relative angle of weaving directions is 5 degrees and 45 degrees. A relative relationship regarding the angle of weaving directions is the same for a case where the angle of weaving directions of the upper-layer mesh member 21 and the lower-layer mesh member 22 is 5 to 45 degrees and a case where the angle of weaving directions is 85 to 45 degrees. Therefore, a range of the relative angle of weaving directions in which the maximum heat-transporting amount Qmax can be maximized is a range within 5 to 85 degrees.

### Second Embodiment

Next, a second embodiment of the present invention will be described.

The first embodiment above has described a case where the liquid-phase flow path 12 is formed by laminating two mesh members 21 and 22. In the second embodiment, however, the liquid-phase flow path 12 is formed by laminating three mesh members. Therefore, that point will mainly be described. It should be noted that in descriptions below, members having the same structures and functions as those of the first embodiment above are denoted by the same symbols, and descriptions thereof will be omitted or simplified.

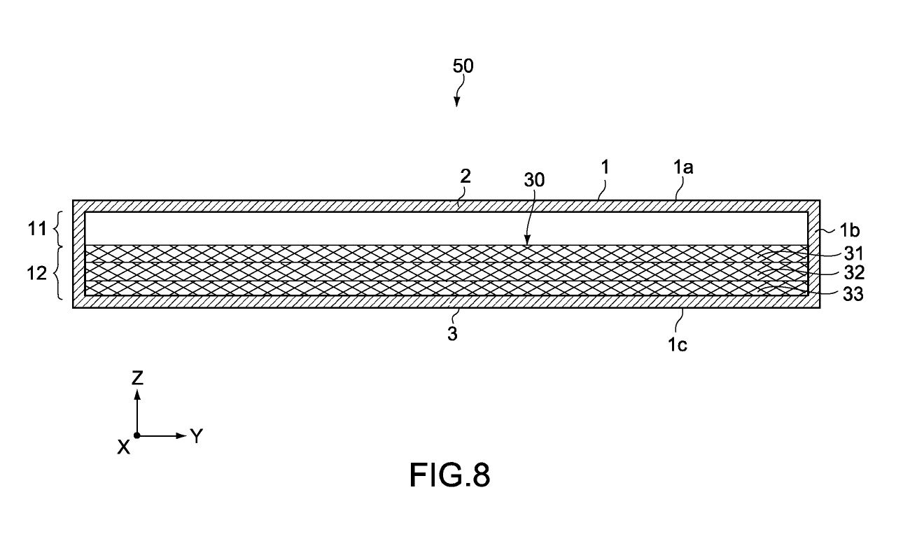

FIG. 8 is a cross-sectional side view of a heat-transporting device according to the second embodiment.

As shown in FIG. 8, a heat-transporting device 50 of the second embodiment includes a laminated body 30 that has three mesh members 31 to 33. In descriptions below, out of the three mesh members, the mesh member 31 as an upper layer will be referred to as upper-layer mesh member 31, the mesh member 32 as an intermediate layer will be referred to as intermediate-layer mesh member 32, and the mesh member 33 as a lower layer will be referred to as lower-layer mesh member 33.

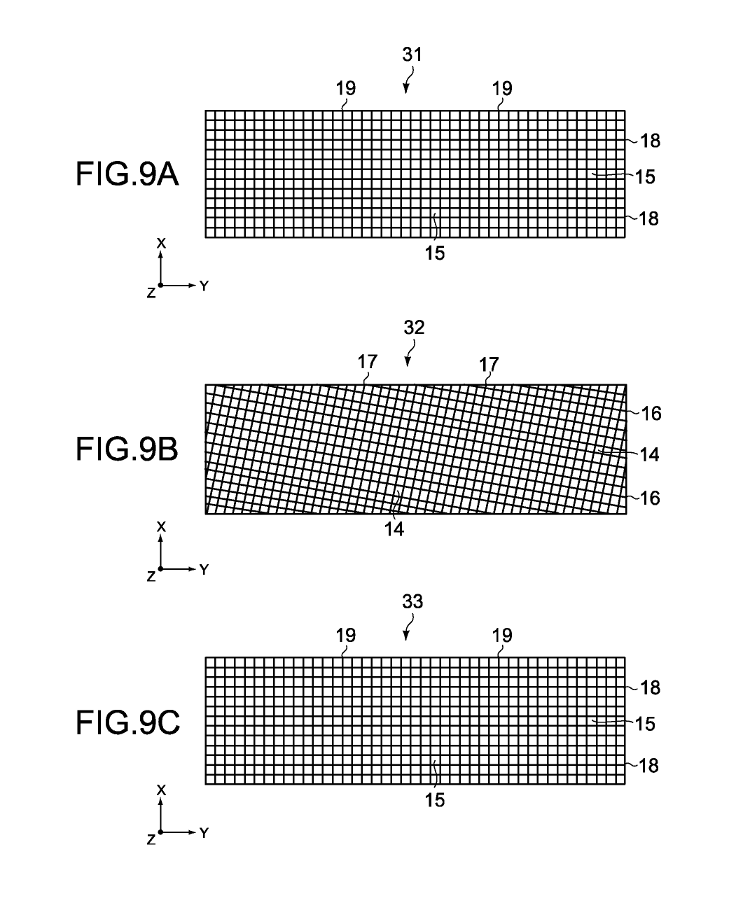

FIG. 9 are plan views of the respective mesh members. FIG. 9A is a plan view of the upper-layer mesh member 31, FIG. 9B is a plan view of the intermediate-layer mesh member 32, and FIG. 9C is a plan view of the lower-layer mesh member 33.

As shown in FIG. 9, the upper-layer mesh member 31 and the lower-layer mesh member 33 have weaving directions in the y- and x-axis directions, whereas the intermediate-layer mesh member 32 has weaving directions in directions that are tilted a predetermined angle with respect to the y- and x-axis directions. In other words, the intermediate-layer mesh member 32 has weaving directions in directions different from those of the upper-layer mesh member 31 and the lower-layer mesh member 33.

Also when the laminated body 30 is formed by laminating the three mesh members 31 to 33 as shown in FIGS. 8 and 9, the same operational effect as in the first embodiment above can be obtained. Specifically, since the mesh members 31 to 33 can be prevented from overlapping each other, a sufficient flow path for causing the liquid-phase working fluid to circulate can be secured. Thus, a flow-path resistance of the liquid-phase working fluid can be reduced and a high capillary force can be generated. As a result, heat-transporting performance of the heat-transporting device 50 can be improved.

FIG. 8 has shown an exemplary case where the upper-layer mesh member 31 and the lower-layer mesh member 33 have weaving directions in the same directions and the intermediate-layer mesh member 32 has weaving directions in directions different from those of the upper-layer mesh member 31 and the lower-layer mesh member 33. However, a combination of the weaving directions of the mesh members 31 to 33 is not limited thereto. For example, the weaving directions of the mesh members 31 to 33 may all be different. The weaving directions of the mesh members only need to be differed for adjacent mesh members, and a combination of the weaving directions of the mesh members 31 to 33 can be changed as appropriate.

The second embodiment has described a case where the liquid-phase flow path 12 is formed by laminating the three mesh members 31 to 33. However, the present invention is not limited thereto, and 4 or more mesh members may be laminated to form a liquid-phase flow path.

### Third Embodiment

Next, a third embodiment of the present invention will be described.

The above embodiments have described cases where the vapor-phase flow path 11 is hollow. However, a heat-transporting device according to the third embodiment is provided with columnar portions 5 in the vapor-phase flow path. Therefore, that point will mainly be described. It should be noted that in descriptions on the third embodiment and subsequent embodiments, points different from those of the second embodiment will mainly be described.

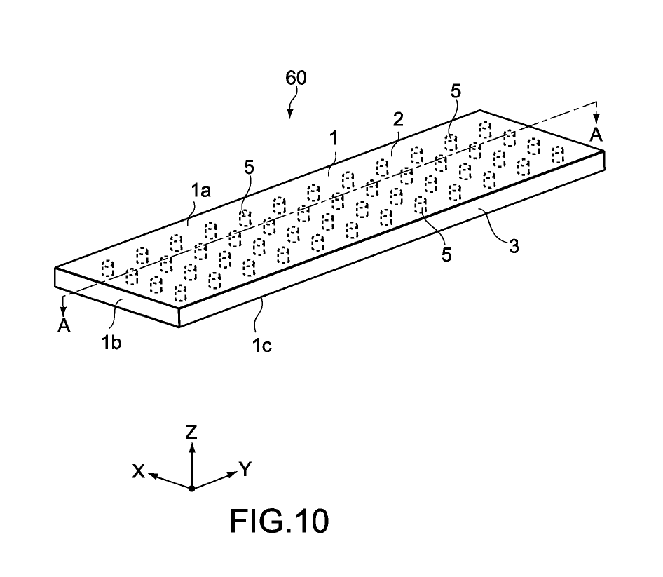

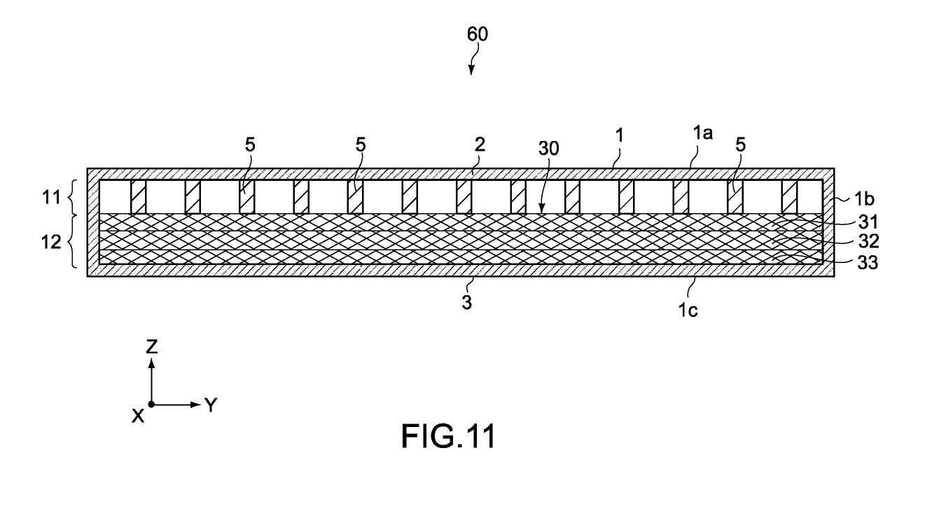

FIG. 10 is a perspective view of a heat-transporting device according to the third embodiment. FIG. 11 is a cross-sectional diagram taken along the line A-A of FIG. 10.

As shown in the figures, in a heat-transporting device 60, the liquid-phase flow path 12 is constituted of three mesh members 31 to 33 and the vapor-phase flow path 11 is provided with a plurality of columnar portions 5. The plurality of columnar portions 5 are arranged in the x- and y-axis directions at predetermined intervals.

The columnar portions 5 are each formed to be cylindrical, though not limited thereto. The columnar portions 5 may each be a quadrangular prism or a polygonal column of a quadrangular prism or more. The shape of the columnar portions 5 is not particularly limited.

The columnar portions 5 are formed by partially etching the upper plate member 2, for example. The method of forming columnar portions 5 is not limited to etching. Examples of the method of forming columnar portions 5 include a metal-plating method, press work, and cutting work.

By forming the columnar portions 5 in the vapor-phase flow path 11 as described above, durability of the heat-transporting device can be enhanced. For example, it becomes possible to prevent the vessel 1 from being deformed due to a pressure at a time an internal temperature of the heat-transporting device 60 increases or a time a working fluid is injected into the heat-transporting device 60 in a reduced-pressure state. In addition, it is possible to enhance durability of the heat-transporting device 60 in a case where the heat-transporting device 60 is subjected to a bending process.

### Fourth Embodiment

Next, a fourth embodiment of the present invention will be described.

The third embodiment above has described a case where the columnar portions 5 are formed in the vapor-phase flow path 11. In the fourth embodiment, however, a mesh member 34 is provided in the vapor-phase flow path 11. Therefore, that point will mainly be described.

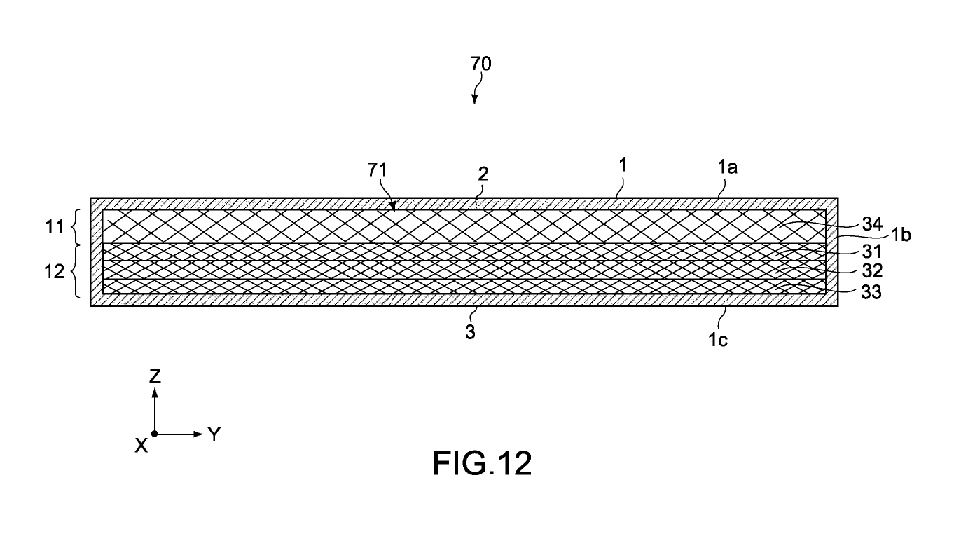

FIG. 12 is a cross-sectional side view of a heat-transporting device according to the fourth embodiment.

As shown in FIG. 12, a heat-transporting device 70 includes a laminated body 71 inside the vessel 1. The laminated body 71 includes the upper-layer mesh member 31, the intermediate-layer mesh member 32, and the lower-layer mesh member 33 that constitute the liquid-phase flow path 12 and the mesh member 34 that constitutes the vapor-phase flow path 11. In descriptions below, the mesh member 34 that constitutes the vapor-phase flow path will be referred to as vapor-phase mesh member 34.

The vapor-phase mesh member 34 is laminated on top of the upper-layer mesh member 31 to thus form a 4-layer laminated body 71.

The vapor-phase mesh member 34 has a mesh number smaller than the mesh numbers of the upper-layer mesh member 31, the intermediate-layer mesh member 32, and the lower-layer mesh member 33. In other words, for the vapor-phase mesh member 34, a mesh member that has rougher meshes than the mesh members 31 to 33 that constitute the liquid-phase flow path 12 is used. For example, the vapor-phase mesh member 34 has a mesh number that is about ⅓ to 1/20 the mesh numbers of the mesh members 31 to 33 that constitute the liquid-phase flow path 12, though not limited thereto.

The vapor-phase mesh member 34 may have weaving directions of meshes in directions different from those of the upper-layer mesh member 31.

Even when the vapor-phase flow path 11 is constituted of the vapor-phase mesh member 34 as in this embodiment, durability of the heat-transporting device 70 can be enhanced as in the third embodiment above. In addition, since both the vapor-phase flow path 11 and the liquid-phase flow path 12 are constituted of a mesh member in the fourth embodiment, a structure is extremely simple. Therefore, it is possible to easily produce a heat-transporting device 70 that has high heat-transporting performance and high durability. Moreover, costs can also be reduced.

### Fifth Embodiment

Next, a fifth embodiment of the present invention will be described.

The above embodiments have described cases where the weaving directions of adjacent mesh members differ. This embodiment, however, is different from the above embodiments in that open stitches of the mesh members differ in the y- and x-axis directions. Therefore, that point will mainly be described.

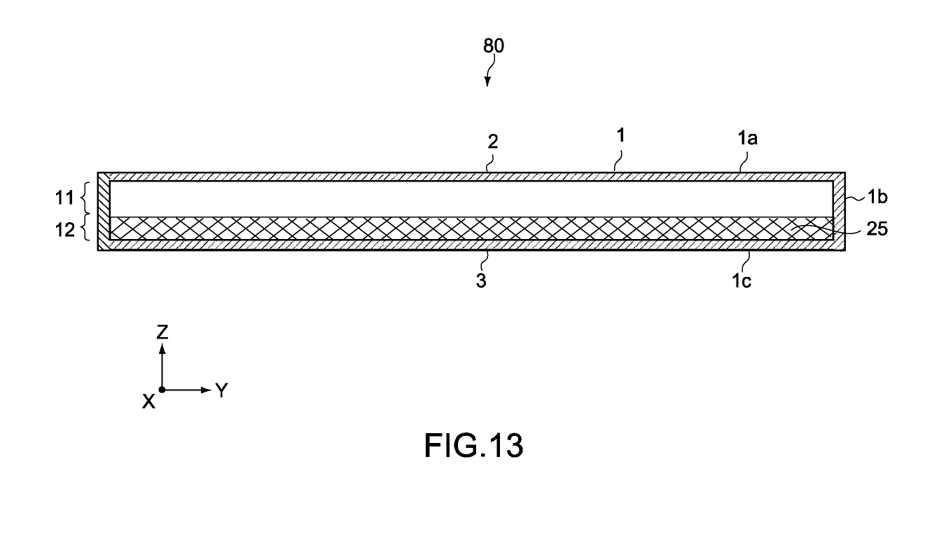

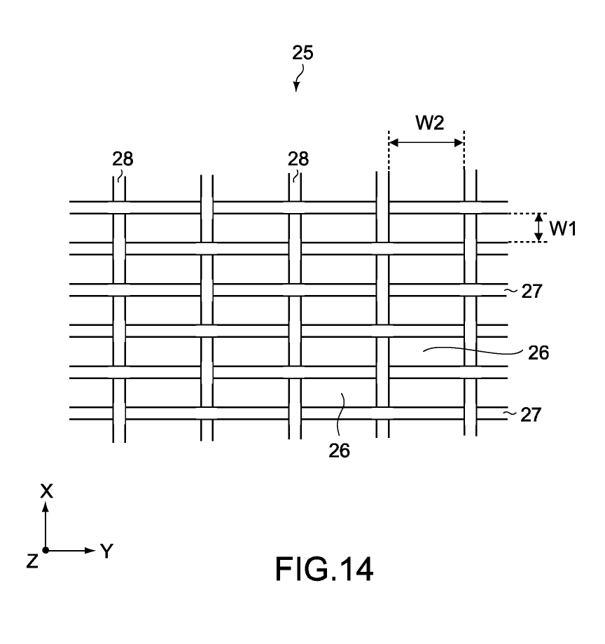

FIG. 13 is a cross-sectional side view of a heat-transporting device according to the fifth embodiment. FIG. 14 is an enlarged plan view of a mesh member.

As shown in FIG. 13, a heat-transporting device 80 includes the hollow vapor-phase flow path 11 on the upper portion 1a side and the liquid-phase flow path 12 on the lower portion 1c side. In this embodiment, the liquid-phase flow path 12 is constituted of a single mesh member 25.

As shown in FIG. 14, the mesh member 25 includes a plurality of first wires 27 that are arranged while extending in the y-axis direction (flow-path direction) and a plurality of second wires 28 that are arranged while extending in the x-axis direction (direction orthogonal to flow-path direction). Moreover, the mesh member 25 includes a plurality of holes 26 that are formed by the first wires 27 and the second wires 28.

The mesh member 25 is formed by orthogonally weaving the first wires 27 and the second wires 28. The mesh member 25 may be formed by twilling, plain weave, or other weaving methods.

The mesh member 25 is formed such that an interval W1 among the first wires 27 and an interval W2 among the second wires 28 differ. In the specification, an interval between wires may be referred to as open stitch. Moreover, in descriptions below, the interval W1 among the first wires 27 will be referred to as first open stitch W1 and the interval W2 among the second wires 28 will be referred to as second open stitch W2.

The second open stitch W2 is formed to be wider than the first open stitch W1. In other words, the second open stitch W2 as an open stitch in a direction along the liquid-phase flow path 12 (y-axis direction) is formed to be wider than the first open stitch W1 as an open stitch in a direction orthogonal to the liquid-phase flow path 12 (x-axis direction).

By thus forming the second open stitch W2 in the direction along the liquid-phase flow path 12 to be wider than the first open stitch W1 in the direction orthogonal to the liquid-phase flow path 12, a flow-path resistance of the liquid-phase working fluid can be reduced. As a result, heat-transporting performance of the heat-transporting device 80 can be improved.

Next, the heat-transporting performance of the heat-transporting device 80 will be described.

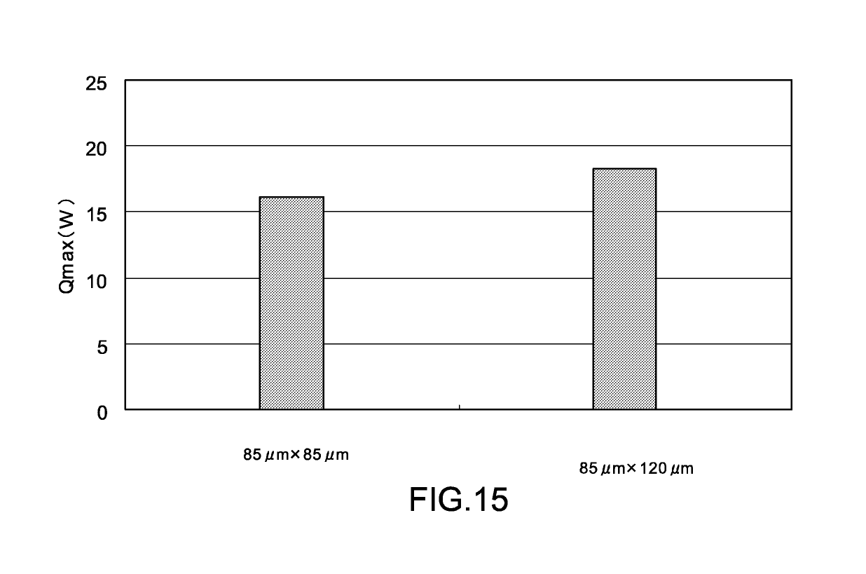

FIG. 15 is a diagram for explaining the heat-transporting performance of the heat-transporting device 80, the diagram showing a relationship between open stitches in y- and x-axis directions and a maximum heat-transporting amount Qmax.

For evaluating the heat-transporting performance of the heat-transporting device 80, the inventors of the present invention prepared a mesh member whose first open stitch W1 and second open stitch W2 are the same and the mesh member 25 whose first open stitch W1 and second open stitch W2 are different. Specifically, an 85 μm×85 μm-size (first open stitch W1×second open stitch W2) mesh member and an 85 μm×120 μm-size mesh member 25 were prepared. The heat-transporting performance is evaluated by comparing maximum heat-transporting amounts Qmax of heat-transporting devices that respectively include those mesh members.

As shown in FIG. 15, a maximum heat-transporting amount Qmax of the heat-transporting device is larger when the first open stitch W1 and the second open stitch W2 differ (85 μm×120 μm) than when the first open stitch W1 and the second open stitch W2 are the same (85 μm×85 μm). In other words, it can be seen from FIG. 15 that the heat-transporting performance is improved by forming the second open stitch W2 in the direction along the liquid-phase flow path 12 to be wider than the first open stitch W1 in the direction orthogonal to the liquid-phase flow path 12.

(Modified Example)

In this embodiment, the description has been given that the liquid-phase flow path 12 is constituted of a single mesh member 25. However, the present invention is not limited thereto, and the liquid-phase flow path 12 may instead be formed by laminating two or more mesh members 25. In this case, the second open stitch W2 is typically formed to be wider than the first open stitch W1 throughout all the laminated mesh members 25. As a result, the heat-transporting performance of the heat-transporting device 80 can be additionally improved.

However, it is not always necessary to form the second open stitch W2 to be wider than the first open stitch W1 throughout all the laminated mesh members 25. For example, the second open stitch W2 of one mesh member 25 out of the plurality of mesh members 25 may be formed to be wider than the first open stitch W1. Also in this case, the heat-transporting performance can be improved as compared to the case where normal mesh members are simply laminated.

Moreover, weaving directions of adjacent mesh members may be differed in a case where the plurality of mesh members 25 are laminated to form the liquid-phase flow path 12. Accordingly, since the mesh members can be prevented from overlapping each other, a flow-path resistance can be additionally reduced. As a result, the heat-transporting performance of the heat-transporting device 80 can be additionally improved.

FIG. 13 has been described assuming that the vapor-phase flow path 11 is hollow. However, the present invention is not limited thereto, and the columnar portions 5 may be provided in the vapor-phase flow path 11 (see FIGS. 10 and 11). Alternatively, the vapor-phase flow path 11 may be constituted of the vapor-phase mesh member 34 (see FIG. 12). As a result, durability of the heat-transporting device 80 can be enhanced.

Particularly when the vapor-phase flow path 11 is constituted of the vapor-phase mesh member 34, the structure thereof is extremely simple. Therefore, the heat-transporting device 80 can be produced easily and costs can also be reduced.

When the vapor-phase flow path 11 is constituted of the vapor-phase mesh member 34, the second open stitch W2 of the vapor-phase mesh member 34 may be formed to be wider than the first open stitch W1. In other words, the vapor-phase mesh member 34 may be formed to have a wider second open stitch W2 in a direction along the vapor-phase flow path 11 than the first open stitch W1 in a direction orthogonal to the vapor-phase flow path 11. Thus, a flow-path resistance of the vapor-phase working fluid can be reduced. As a result, the heat-transporting performance of the heat-transporting device 80 can be improved.

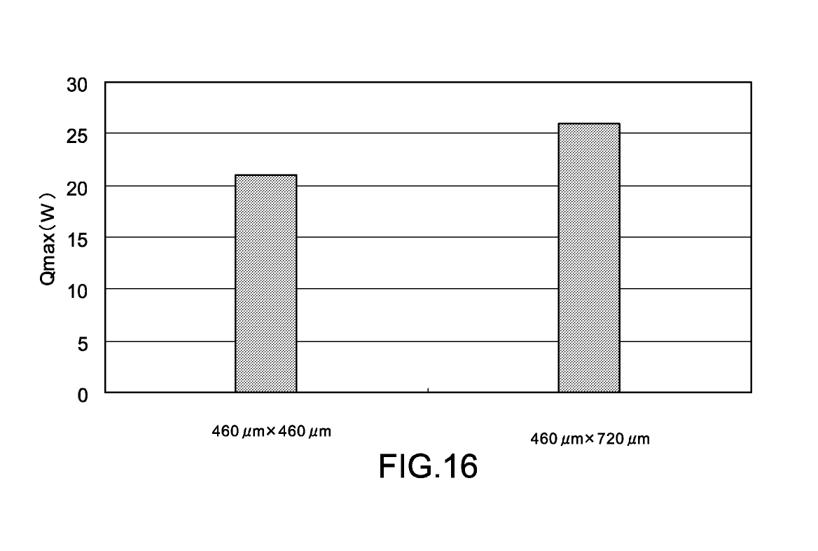

FIG. 16 is a diagram showing a relationship between open stitches of the vapor-phase mesh member in the y- and x-axis directions and the maximum heat-transporting amount Qmax.

The inventors of the present invention prepared a 460 μm×460 μm-size (first open stitch W1×second open stitch W2) vapor-phase mesh member 34 and a 460 μm×720 μm-size vapor-phase mesh member 34, to thus evaluate the heat-transporting performance.

As can be seen from FIG. 16, the maximum heat-transporting amount Qmax of the heat-transporting device is larger when the open stitches differ for the y- and x-axis directions (460 μm×720 μm) than when the open stitches are the same for the y- and x-axis directions (460 μm×460 μm). In other words, it can be seen from FIG. 16 that the heat-transporting performance is improved by forming the second open stitch W2 of meshes in the direction along the vapor-phase flow path 11 to be wider than the first open stitch W1 of the meshes in the direction orthogonal to the vapor-phase flow path 11.

### Sixth Embodiment

Next, a sixth embodiment of the present invention will be described.

The sixth embodiment is different from the above embodiments in that mesh numbers of adjacent mesh members that constitute the liquid-phase flow path differ. Therefore, that point will mainly be described.

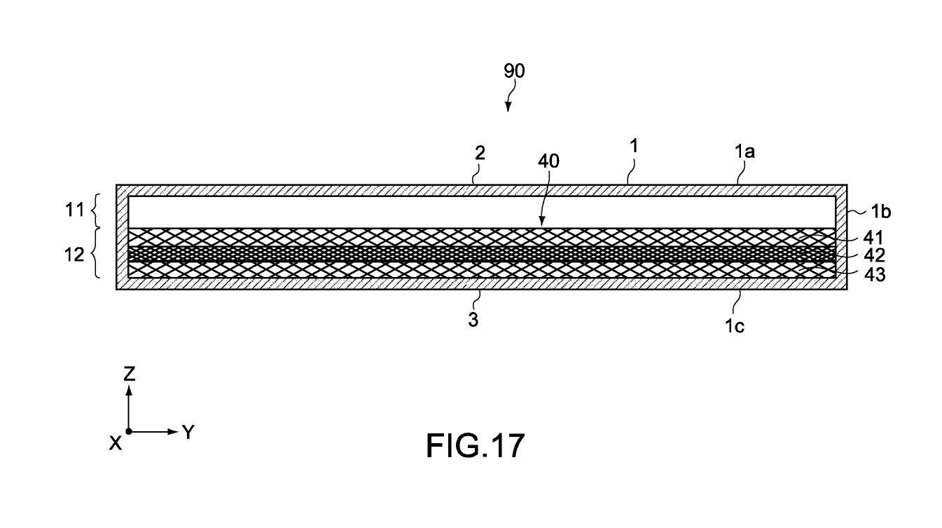

FIG. 17 is a cross-sectional side view of a heat-transporting device according to the sixth embodiment.

As shown in FIG. 17, a heat-transporting device 90 includes the vapor-phase flow path 11 on the upper portion 1a side and the liquid-phase flow path 12 on the lower portion 1c side. The vapor-phase flow path 11 is hollow, and the liquid-phase flow path 12 is constituted of a laminated body 40. The laminated body 40 includes an upper-layer mesh member 41 as an upper layer, an intermediate-layer mesh member 42 as an intermediate layer, and a lower-layer mesh member 43 as a lower layer.

The laminated body 40 is formed by laminating the mesh members 41 to 43 having different mesh numbers. In other words, the laminated body 40 is formed by laminating the mesh members 41 to 43 that have different mesh roughness. It should be noted that the mesh numbers only need to differ for adjacent mesh members.

For example, the mesh number of the upper-layer mesh member 41 is set to #100, that of the intermediate-layer mesh member 42 is set to #150, and that of the lower-layer mesh member 43 is set to #100.

However, the combination of the mesh numbers is not limited thereto. For example, the mesh numbers of the mesh members 41 to 43 may be set to #200, #150, and #200 or #200, #150, and #100 sequentially from the upper layer. Regarding the combination of the mesh numbers, the mesh numbers only need to differ for adjacent mesh members, and the combination of the mesh numbers can be changed as appropriate.

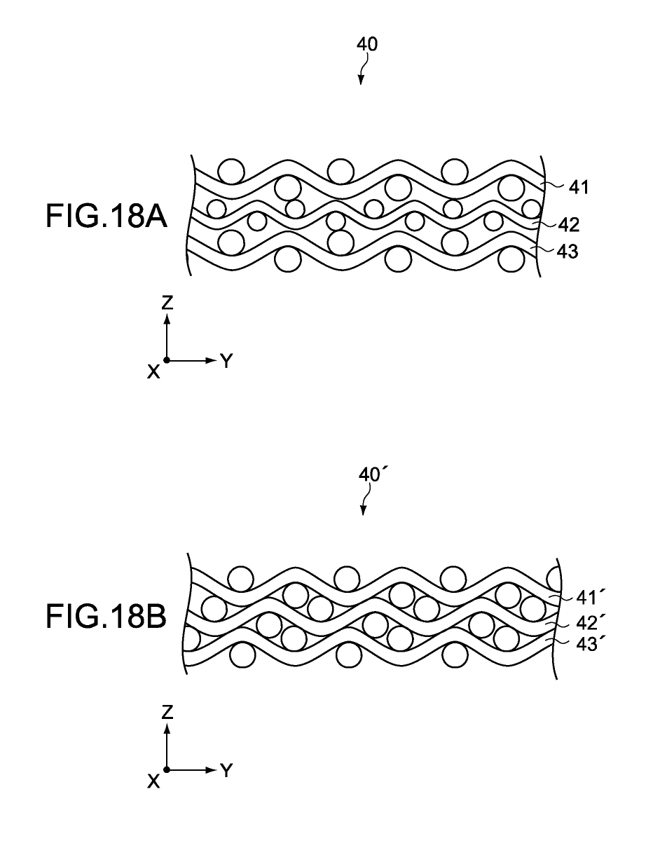

FIG. 18 are each an enlarged cross-sectional diagram of a laminated body. FIG. 18A is an enlarged cross-sectional diagram of the laminated body 40, and FIG. 18B is an enlarged cross-sectional diagram of a laminated body 40′ according to a comparative example.

First, the laminated body 40′ according to the comparative example will be described with reference to FIG. 18B. The laminated body 40′ of the comparative example is formed by laminating mesh members 41′ to 43′ that have the same mesh number.

As shown in FIG. 18B, in the laminated body 40′ that is formed by laminating the mesh members 41′ to 43′ of the same mesh number, the mesh members 41′ to 43′ overlap each other. In this case, since a sufficient space for causing the liquid-phase working fluid to circulate cannot be secured, a flow-path resistance of the liquid-phase working fluid becomes large. Moreover, a capillary force cannot be fully exerted.

On the other hand, by forming the laminated body 40 while differentiating the mesh numbers of the mesh members 41′ to 43′ that are adjacent to each other as shown in FIG. 18A, the mesh members 41 to 43 can be prevented from overlapping each other. Accordingly, a sufficient flow path for causing the liquid-phase working fluid to circulate can be secured. Thus, a flow-path resistance of the liquid-phase working fluid can be reduced and a high capillary force can be generated. As a result, heat-transporting performance of the heat-transporting device 90 can be improved.

Next, a relationship between mesh numbers of mesh members that are adjacent to each other and the heat-transporting performance of the heat-transporting device will be described.

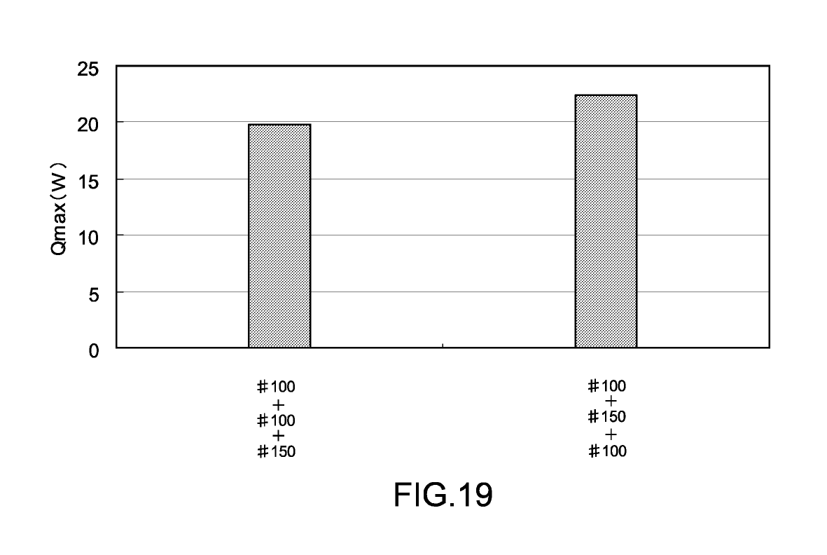

FIG. 19 is a diagram showing a relationship between the mesh numbers of mesh members that are adjacent to each other and the heat-transporting performance of the heat-transporting device. For examining the relationship, a laminated body 40 in which mesh numbers are set to #150, #100, and #100 sequentially from the upper layer and a laminated body 40 in which mesh numbers are set to #100, #150, and #100 sequentially from the upper layer were prepared.

As shown in FIG. 19, a maximum heat-transporting amount Qmax of the heat-transporting device 90 is larger when the mesh numbers are set to #100, #150, and #100 sequentially from the upper layer than when the mesh numbers are set to #150, #100, and #100 sequentially from the upper layer. In other words, it can be seen from FIG. 19 that the heat-transporting performance of the heat-transporting device 90 can be improved by differentiating the mesh numbers of the mesh members 41 to 43 that are adjacent to each other.

It should be noted that when the mesh numbers are set to #150, #100, and #100 sequentially from the upper layer, the mesh number of the intermediate-layer mesh member 42 and the mesh number of the lower-layer mesh member 43 are the same. However, the mesh number of the upper-layer mesh member 41 and the mesh number of the intermediate-layer mesh member 42 differ. Therefore, in this case, the heat-transporting performance is improved as compared to a case where the mesh numbers of the mesh members 41 to 43 are the same (e.g., #100, #100, and #100 sequentially from upper layer).

Next, an overlap of mesh members due to periodicities thereof will be described.

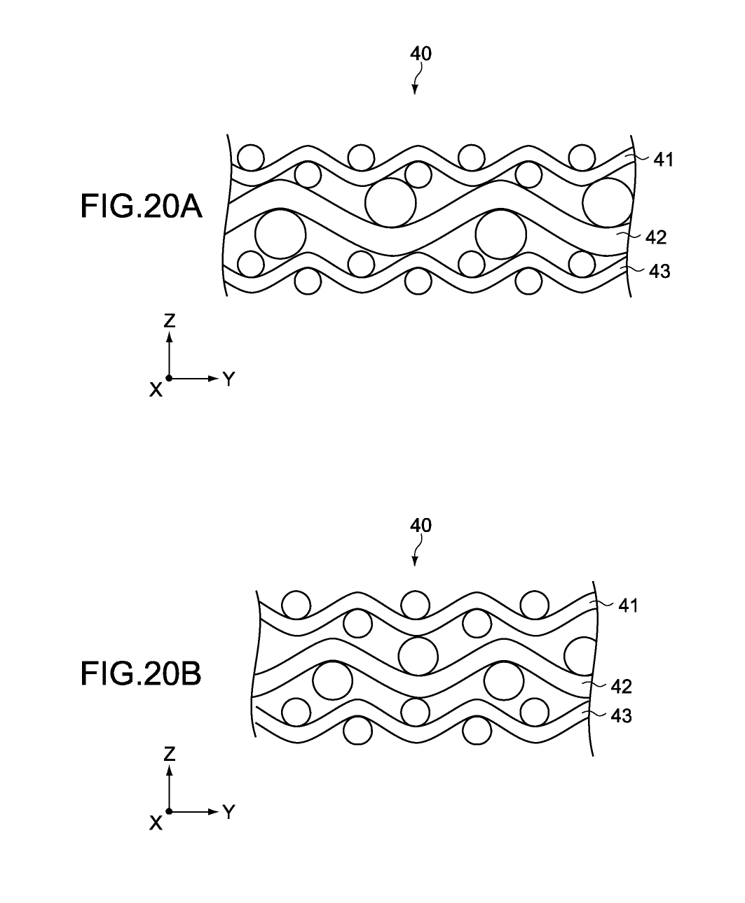

FIG. 20 are enlarged cross-sectional diagrams of the laminated body 40 for explaining an overlap of the mesh members due to periodicities thereof. FIG. 20A is a cross-sectional diagram of the laminated body 40 in a case where the mesh numbers are set to #100, #200, and #100 sequentially from the upper layer, and FIG. 20B is a cross-sectional diagram of the laminated body 40 in a case where the mesh numbers are set to #100, #150, and #100 sequentially from the upper layer.

As shown in FIG. 20A, when the mesh number of the intermediate-layer mesh member 42 (#200) is twice as large as the mesh numbers of the upper-layer mesh member 41 and the lower-layer mesh member 43 (#100), periodicities of the mesh members 41 to 43 are synchronized. As a result, the mesh members 41 to 43 that are adjacent to each other may overlap each other.

On the other hand, as shown in FIG. 20B, when the mesh number of the intermediate-layer mesh member 42 is set to #150 and the mesh numbers of the upper-layer mesh member 41 and lower-layer mesh member 43 are set to #100, the periodicities of the mesh members 41 to 43 can be prevented from being synchronized. Thus, the mesh members 41 to 43 that are adjacent to each other can be prevented from overlapping each other. As a result, heat-transporting performance can be additionally improved.

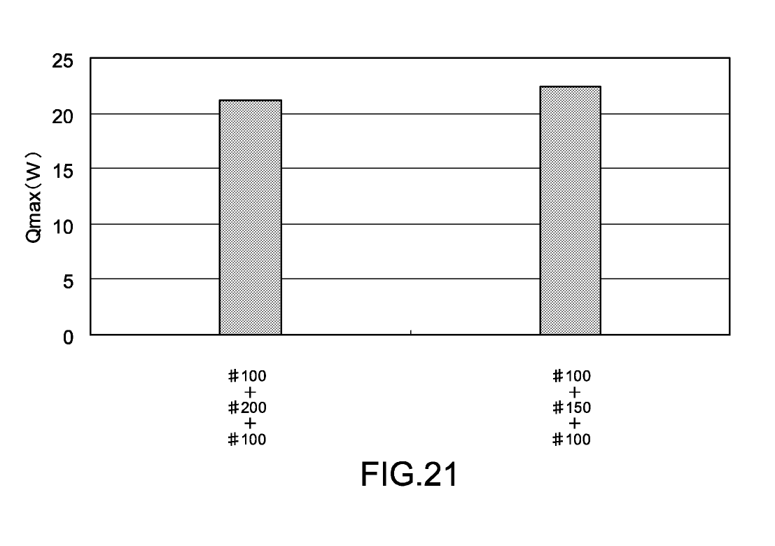

FIG. 21 is a diagram obtained as a result of comparing heat-transporting performance of heat-transporting devices respectively including the laminated bodies shown in FIG. 20.

As shown in FIG. 21, a maximum heat-transporting amount Qmax of the heat-transporting device 90 is larger when the mesh numbers are set to #100, #150, and #100 sequentially from the upper layer than when the mesh numbers are set to #100, #200, and #100 sequentially from the upper layer. In other words, the heat-transporting performance of the heat-transporting device 90 is improved more in a case where the mesh number of one of the adjacent mesh members is other than a mesh number that is twice as large as (or ½) the mesh number of the other one of the adjacent mesh members than in a case where the mesh number is twice as large as (or ½) the mesh number of the adjacent mesh member.

It should be noted that the descriptions on FIGS. 20 and 21 have been given on the case where the mesh number is twice as large as the adjacent mesh number. However, also in a case where the mesh number is three times the mesh number of the adjacent mesh member, the periodicities of the mesh members 41 to 43 may be synchronized to thus cause an overlap of the mesh members 41 to 43.

Therefore, the mesh numbers of the mesh members 41 to 43 that are adjacent to each other are typically set so that each of the mesh numbers is other than twice or three times (½ or ⅓) the mesh number of the adjacent mesh member. For example, each of the mesh numbers of the mesh members 41 to 43 that are adjacent to each other is set to be ⅔, ¼, ¾, ⅕, ⅖, ⅗, ⅘, four times, or five times the mesh number of the adjacent mesh member.

(Modified Example)

The descriptions on the sixth embodiment have been given on a case where the liquid-phase flow path 12 is constituted of three mesh members 41 to 43. However, the present invention is not limited thereto, and the liquid-phase flow path 12 may be constituted of two mesh members or four or more mesh members. In such a case, the laminated body 40 is typically formed such that the mesh numbers of the mesh members that are adjacent to each other differ throughout all the laminated mesh members. However, the laminated body 40 does not necessarily need to be formed such that the mesh numbers of the mesh members that are adjacent to each other differ throughout all the laminated mesh members. For example, a mesh number of one mesh member out of a plurality of mesh members may differ from those of the other mesh members. Also in such a case, heat-transporting performance can be improved as compared to the case where normal mesh members are simply laminated.

Weaving directions of at least one mesh member out of the mesh members 41 to 43 described above may differ from those of the other mesh members. In other words, the mesh numbers and weaving directions of the mesh members 41 to 43 that are adjacent to each other may differ. As a result, an effect of preventing the mesh members 41 to 43 from overlapping each other is additionally enhanced and the heat-transporting performance of the heat-transporting device 90 can be additionally improved.

Alternatively, open stitches of at least one mesh member out of the mesh members 41 to 43 may differ for the y- and x-axis directions. In other words, the mesh numbers of the mesh members 41 to 43 that are adjacent to each other and open stitches thereof in the y- and x-axis directions may both be different. As a result, the heat-transporting performance of the heat-transporting device 90 can be additionally improved.

Alternatively, the weaving directions, open stitches in the y- and x-axis directions, and mesh numbers regarding the mesh members that are adjacent to each other may all differ.

The descriptions on FIG. 17 have been given assuming that the vapor-phase flow path 11 is hollow. However, the present invention is not limited thereto, and the columnar portions 5 may be provided in the vapor-phase flow path 11 (see FIGS. 10 and 11). Alternatively, the vapor-phase flow path 11 may be constituted of the vapor-phase mesh member 34 (see FIG. 12). When the vapor-phase flow path 11 is constituted of the vapor-phase mesh member 34, the weaving directions of the vapor-phase mesh member 34 and/or open stitches thereof in the y- and x-axis directions may differ.

### Seventh Embodiment

Next, a seventh embodiment of the present invention will be described.

The above embodiments have been described assuming that the vessel 1 is constituted of two plate members 2 and 3. In the seventh embodiment, however, the vessel is formed by bending a single plate member. Therefore, that point will mainly be described.

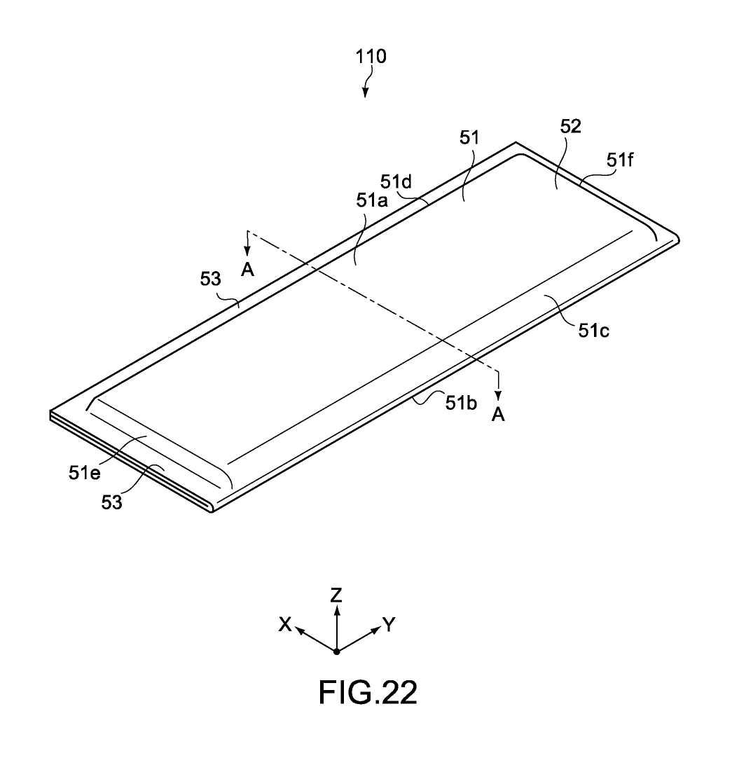

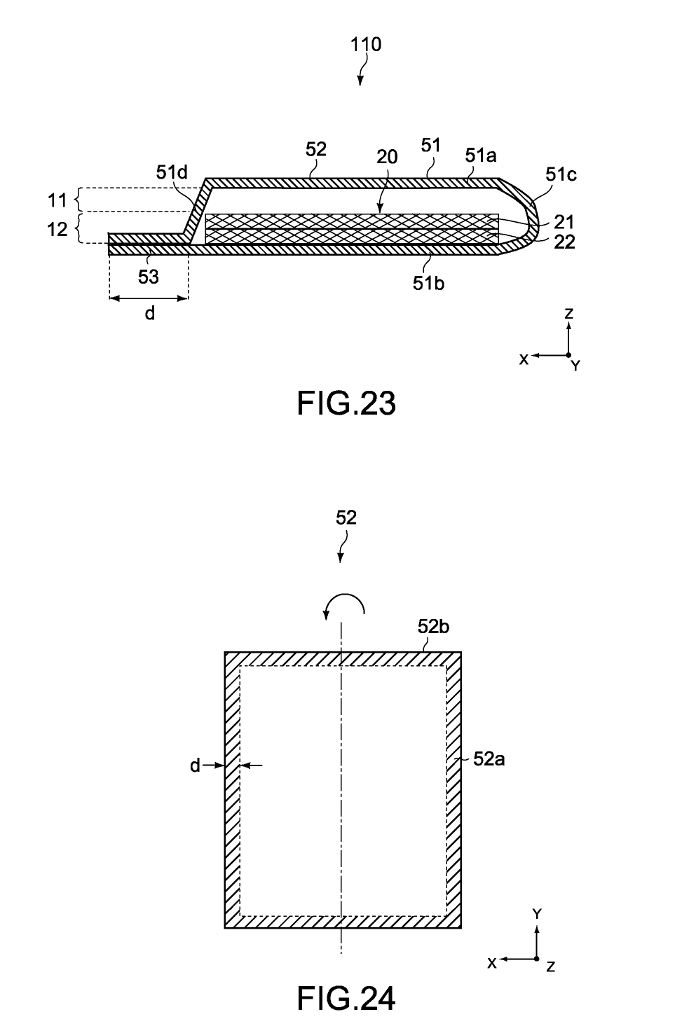

FIG. 22 is a perspective view of a heat-transporting device according to the seventh embodiment. FIG. 23 is a cross-sectional diagram taken along the line A-A of FIG. 22. FIG. 24 is a development view of a plate member that constitutes a vessel of the heat-transporting device.

As shown in FIG. 22, a heat-transporting device 110 includes a thin rectangular plate-like vessel 51 that is elongated in one direction (y-axis direction). The vessel 51 is formed by bending a single plate member 52.

Typically, the plate member 52 is constituted of oxygen-free copper, tough pitch copper, or a copper alloy. However, the present invention is not limited thereto, and the plate member 52 may be constituted of metal other than copper or other materials having a high heat conductivity.

As shown in FIGS. 22 and 23, a side portion 51c of the vessel 51 in a direction along a longitudinal direction (y-axis direction) is curved. In other words, since the vessel 51 is formed by bending substantially the center of the plate member 52 shown in FIG. 24, the side portion 51c is curved. In descriptions below, the side portion 51c may be referred to as curved portion 51c.

The vessel 51 includes a side portion 51d on the other side of the side portion 51c (curved portion 51c) and bonding portions 53 at side portions 51e and 51f along a short-side direction. The bonding portions 53 protrude from the side portions 51d, 51e, and 51f. At the bonding portions 53, the bent plate member 52 is bonded. The bonding portions 53 correspond to a bonding area 52a of the plate member 52 shown in FIG. 24 (area indicated by slashes in FIG. 24). The bonding area 52a is an area within a predetermined distance d from an edge portion 52b of the plate member 52.

Examples of the method of bonding the bonding portions 53 (bonding area 52a) include a diffusion bonding method, an ultrasonic bonding method, a brazing method, and a welding method, but the bonding method is not particularly limited.

Inside of the vessel 51 is hollow on an upper portion 51a side, and this cavity constitutes the vapor-phase flow path 11. Further, inside the vessel 51, the laminated body 20 disposed on a lower portion 51b side constitutes the liquid-phase flow path 12.

The laminated body 20 includes the upper-layer mesh member 21 and the lower-layer mesh member 22. The upper-layer mesh member 21 and the lower-layer mesh member 22 are laminated such that weaving directions thereof differ as described above.

It should be noted that the structures of the vapor-phase flow path 11 and the liquid-phase flow path 12 are not limited to those shown in FIG. 23. For example, the columnar portions 5 may be provided in the vapor-phase flow path 11 (see FIGS. 10 and 11) or the vapor-phase flow path 11 may be constituted of the vapor-phase mesh member 34 (see FIG. 12). Moreover, the liquid-phase flow path 12 may be constituted of the mesh member 25 having different open stitches in the y- and x-axis directions, or the liquid-phase flow path 12 may be formed by laminating the mesh members 41 to 43 having different mesh numbers. All the structures of the vapor-phase flow path 11 and liquid-phase flow path 12 described in the above embodiments are applicable to the seventh embodiment. The same holds true for embodiments to be described later.

(Method of Producing Heat-Transporting Device)

Next, a method of producing a heat-transporting device 110 will be described.

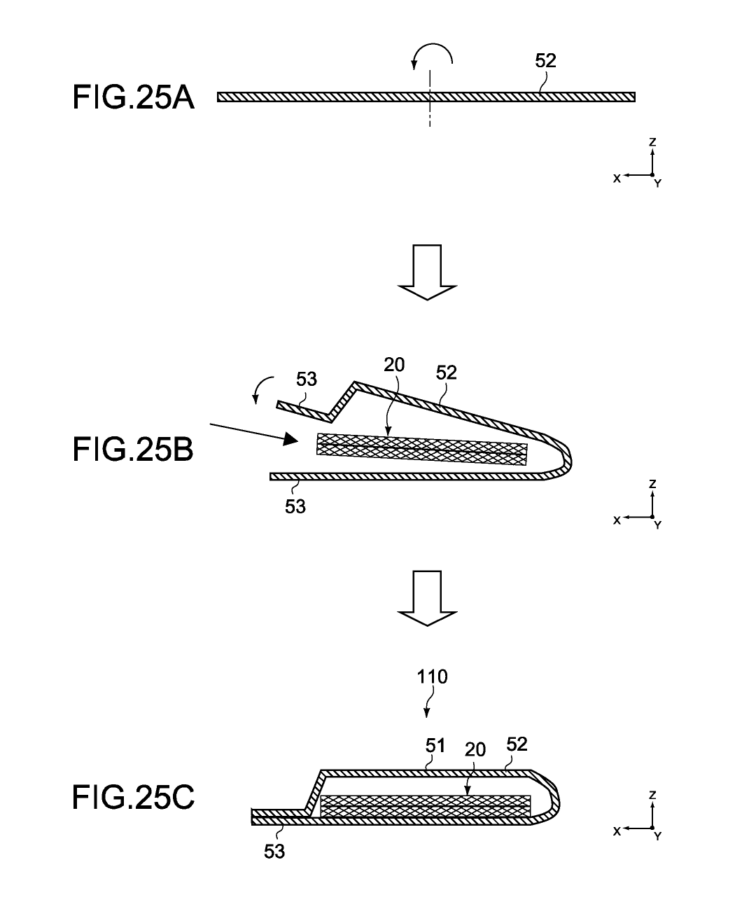

FIG. 25 are diagrams showing the method of producing a heat-transporting device.

As shown in FIG. 25A, the plate member 52 is prepared first. Then, the plate member 52 is bent at substantially the center thereof.

After the plate member 52 is bent to a predetermined angle, the laminated body 20 is inserted between the bent plate member 52 as shown in FIG. 25B. It should be noted that it is also possible to set the laminated body 20 at a predetermined position on the plate member 52 before the plate member 52 is bent.

After the laminated body 20 is inserted between the bent plate member 52, the plate member 52 is bent further so as to enclose the laminated body 20 inside as shown in FIG. 25C. Then, the bonding portions 53 (bonding area 52a) of the bent plate member 52 are bonded. As the method of bonding the bonding portions 53, a diffusion bonding method, an ultrasonic bonding method, a brazing method, a welding method, and the like are used as described above.

Since the vessel 51 is constituted of a single plate member 52 in the heat-transporting device 110 according to the seventh embodiment, costs can be reduced. Further, although, when the vessel 1 is constituted of two or more members, those members need to be aligned in position, alignment of positions of the members is not necessary in the heat-transporting device 110 of the seventh embodiment. Therefore, the heat-transporting device 110 can be produced with ease. It should be noted that although a structure in which the plate member 52 is bent with an axis along the longitudinal direction (y-axis direction) is shown, it is also possible for the plate member 52 to be bent with an axis along the short-side direction (x-axis direction).

(Modified Example)

Next, a modified example of the heat-transporting device according to the seventh embodiment will be described.

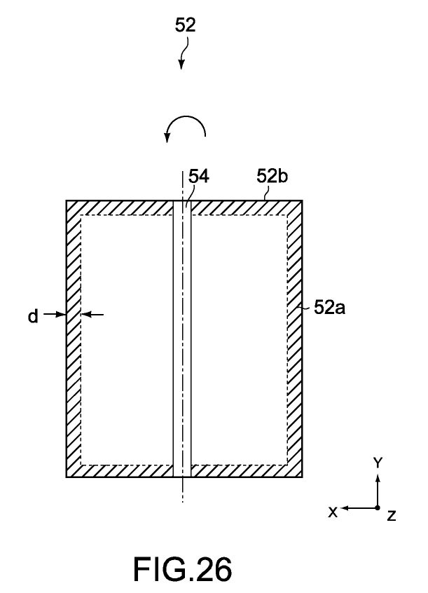

FIG. 26 is a development view of the plate member for explaining the modified example.

As shown in FIG. 26, the plate member 52 includes a groove 54 at a center thereof along a longitudinal direction (y-axis direction). The groove 54 is formed by, for example, press work or etching, but the method of forming the groove 54 is not particularly limited.

By providing the groove 54 on the plate member 52, the plate member 52 can be bent easily. As a result, it becomes easier to produce the heat-transporting device 110.

### Eighth Embodiment

Next, an eighth embodiment of the present invention will be described. It should be noted that in the eighth embodiment, points different from those of the seventh embodiment will mainly be described.

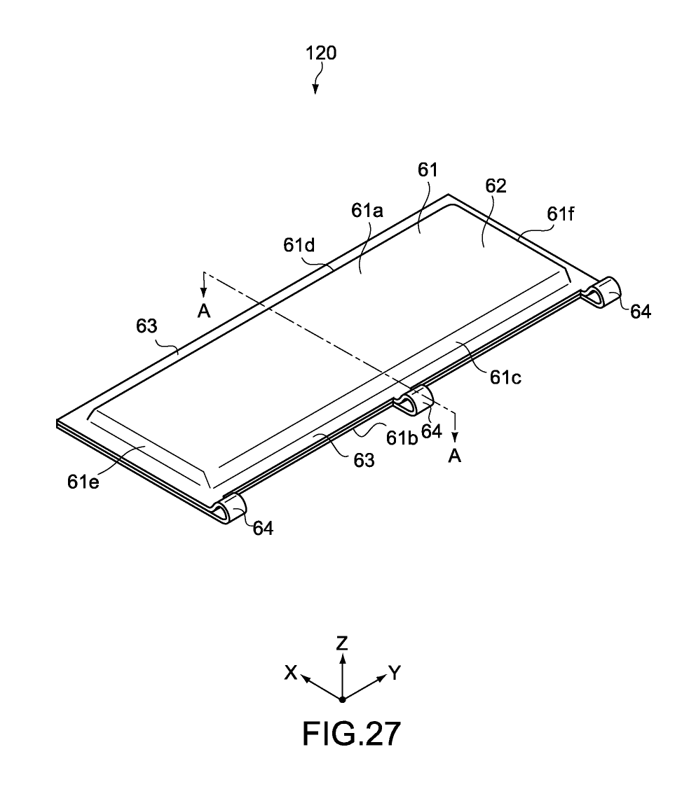

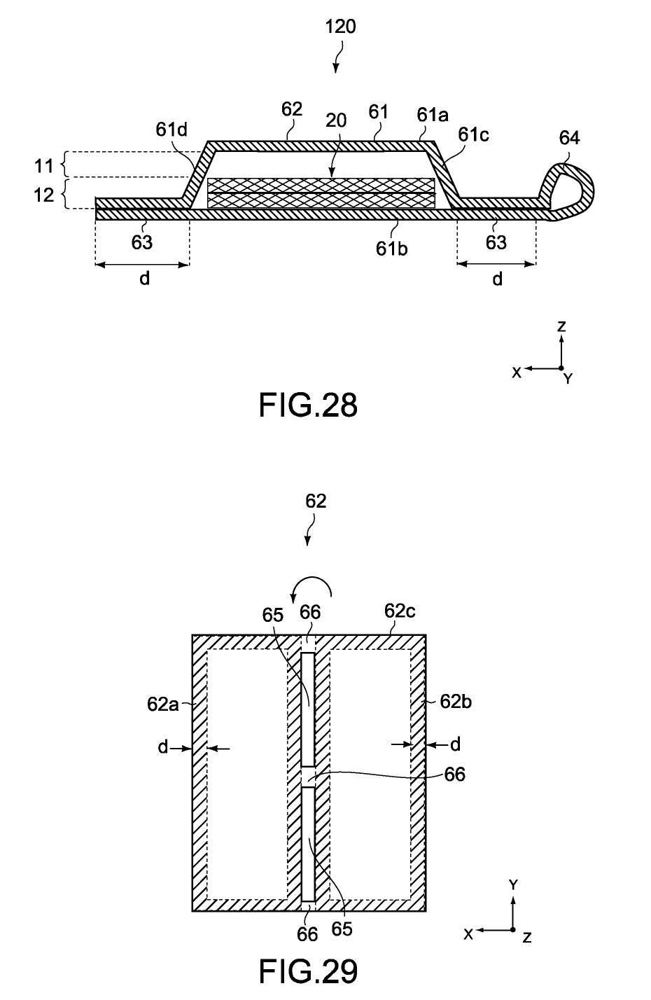

FIG. 27 is a perspective view of a heat-transporting device according to the eighth embodiment. FIG. 28 is a cross-sectional diagram taken along the line A-A of FIG. 27. FIG. 29 is a development view of a plate member that constitutes a vessel of the heat-transporting device.

As shown in FIGS. 27 and 28, a heat-transporting device 120 includes a thin rectangular plate-like vessel 61 that is elongated in one direction (y-axis direction).

The vessel 61 is formed by bending a plate member 62 shown in FIG. 29 at a center thereof. The plate member 62 is provided with two openings 65 near the center along a longitudinal direction thereof.

The vessel 61 includes bonding portions 63 at side portions 61c and 61d in a direction along the longitudinal direction (y-axis direction) and side portions 61e and 61f in a direction along a short-side direction (x-axis direction). The vessel 61 is formed by bonding the bonding portions 63. The bonding portions 63 correspond to bonding areas 62a and 62b of the plate member 62 shown in FIG. 29 (area indicated by slashes in FIG. 29). The bonding areas 62a and 62b are arranged axisymmetrically on left- and right-hand sides of the plate member 62. The bonding areas 62a and 62b are areas within a predetermined distance d from an edge portion 62c or the openings 65 of the plate member 62.

The bonding portion 63 provided at the side portion 61c of the vessel 61 includes three protrusions 64. The three protrusions 64 are bent. The three protrusions 64 correspond to areas 66 each between the opening 65 and the edge portion 62c and an area 66 between the two openings 65 on the plate member 62 shown in FIG. 29.

Inside of the vessel 61 is hollow on an upper portion 61a side, and this cavity constitutes the vapor-phase flow path 11. Moreover, inside the vessel 61, the laminated body 20 disposed on a lower portion 61b side constitutes the liquid-phase flow path 12.

Since the openings 65 are formed on the plate member 62 in the heat-transporting device 120 of the eighth embodiment, the plate member 62 can be bent with ease. As a result, it becomes easier to produce the heat-transporting device 120.

It is also possible to form a groove in the areas 66 each between the opening 65 and the edge portion 62c and the area 66 between the two openings 65 by press work, for example. Accordingly, the plate member 62 can be bent more easily. It should be noted that although a structure in which the plate member 62 is bent with an axis along the longitudinal direction (y-axis direction) is shown, it is also possible for the plate member 62 to be bent with an axis along the short-side direction (x-axis direction).

(Electronic Apparatus)

Next, an electronic apparatus including the heat-transporting device 10 (or 50 to 120; the same holds true for descriptions below) described in the corresponding embodiment above will be described. This embodiment exemplifies a laptop PC as the electronic apparatus.

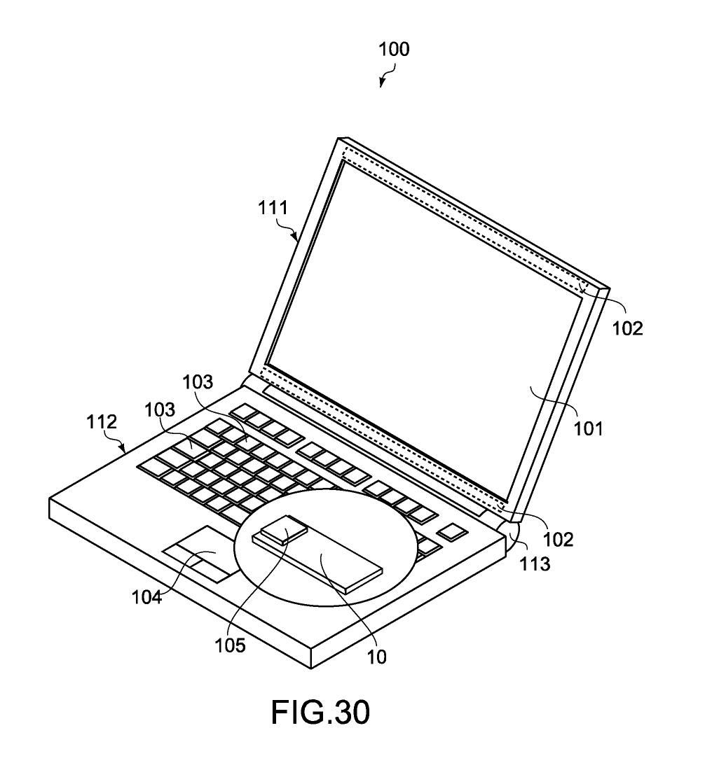

FIG. 30 is a perspective view of a laptop PC 100. As shown in FIG. 30, the laptop PC 100 includes a first casing 111, a second casing 112, and a hinge portion 113 that rotatably supports the first casing 111 and the second casing 112.

The first casing 111 includes a display portion 101 and edge-light-type backlights 102 that irradiate light onto the display portion 101. The backlights 102 are respectively provided on upper and lower sides inside the first casing 111. The backlights 102 are each formed by arranging a plurality of white-color LEDs (Light-emitting Diodes) on a copper plate, for example.

The second casing 112 includes a plurality of input keys 103 and a touchpad 104. The second casing 112 also includes a built-in control circuit board (not shown) on which electronic circuit components such as a CPU 105 are mounted.

Inside the second casing 112, the heat-transporting device 10 is set so as to come into contact with the CPU 105. In FIG. 30, a plane of the heat-transporting device 10 is illustrated to be smaller than that of the second casing 112. However, the heat-transporting device 10 may have an equivalent plane size as the second casing 112.

Alternatively, the heat-transporting device 10 may be set inside the first casing 111 while being in contact with the copper plates constituting the backlights 102. In this case, the heat-transporting device 10 is provided plurally in the first casing 111.

As described above, due to high heat-transporting performance, the heat-transporting device 10 can readily transport heat generated in the CPU 105 or the backlights 102. Accordingly, heat can be readily radiated outside the laptop PC 100. Moreover, since an internal temperature of the first casing 111 or the second casing 112 can be made uniform by the heat-transporting device 10, low-temperature burn can be prevented.

Furthermore, since high heat-transporting performance is realized in a thin heat-transporting device 10, thinning of the laptop PC 100 can also be realized.

FIG. 30 has exemplified the laptop PC as the electronic apparatus. However, the electronic apparatus is not limited thereto, and other examples of the electronic apparatus include audiovisual equipment, a display apparatus, a projector, game equipment, car navigation equipment, robot equipment, a PDA (Personal Digital Assistance), an electronic dictionary, a camera, a cellular phone, and other electrical appliances.

The heat-transporting device and electronic apparatus described heretofore are not limited to the above embodiments, and various modifications are possible.

The above embodiments have described cases where the liquid-phase flow path 12 is constituted of a mesh member. However, the present invention is not limited thereto, and a part of the liquid-phase flow path 12 may be formed of a material other than the mesh member. Examples of the material other than the mesh member include felt, a metal form, a thin line, a sintered body, and a microchannel including fine grooves.

The present application contains subject matter related to that disclosed in Japanese Priority Patent Application JP 2008-328870 filed in the Japan Patent Office on Dec. 24, 2008, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A heat-transporting device, comprising:
a working fluid to transport heat using a phase change;
a vessel to seal in the working fluid;
a vapor-phase flow path to cause the working fluid in a vapor phase to circulate inside the vessel; and
a liquid-phase flow path that includes a laminated body and causes the working fluid in a liquid phase to circulate inside the vessel, the laminated body including a first mesh member and a second mesh member and being formed such that the first mesh member and the second mesh member are laminated while weaving directions thereof differ relatively.

2. The heat-transporting device according to claim 1,
wherein at least one of the first mesh member and the second mesh member includes a plurality of first wires that are arranged at first intervals and a plurality of second wires that are woven into the plurality of first wires and arranged at second intervals different from the first intervals.

3. The heat-transporting device according to claim 1,
wherein the first mesh member has a first mesh number, and
wherein the second mesh member has a second mesh number different from the first mesh number.

4. The heat-transporting device according to claim 1,
wherein a relative angle of the weaving directions of the first mesh member and the second mesh member ranges from 5 degrees to 85 degrees.

5. The heat-transporting device according to claim 1,
wherein the vapor-phase flow path includes a third mesh member.

6. The heat-transporting device according to claim 1,
wherein the vessel is plate-like.

7. The heat-transporting device according to claim 6,
wherein the vessel is formed by bending a plate member so that the laminated body is sandwiched by the bent plate member.

8. The heat-transporting device according to claim 7,
wherein the plate member includes an opening in an area where the plate member is bent.

9. A heat-transporting device, comprising:
a working fluid to transport heat using a phase change;
a vessel to seal in the working fluid;
a vapor-phase flow path to cause the working fluid in a vapor phase to circulate inside the vessel; and
a liquid-phase flow path that includes a first mesh member and causes the working fluid in a liquid phase to circulate inside the vessel, the first mesh member including a plurality of first wires that are arranged at first intervals and a plurality of second wires that are woven into the plurality of first wires and arranged at second intervals different from the first intervals.

10. The heat-transporting device according to claim 9,
wherein the vapor-phase flow path includes a second mesh member including a plurality of third wires that are arranged at third intervals and a plurality of fourth wires that are woven into the plurality of third wires and arranged at fourth intervals different from the third intervals.

11. The heat-transporting device according to claim 9,
wherein the plurality of first wires are arranged such that each of the plurality of first wires extends in a direction along the liquid-phase flow path,
wherein the plurality of second wires are arranged such that each of the plurality of second wires extends in a direction orthogonal to the direction along the liquid-phase flow path, and
wherein the second intervals are wider than the first intervals.

12. The heat-transporting device according to claim 10,
wherein the plurality of third wires are arranged such that each of the plurality of third wires extends in a direction along the vapor-phase flow path,
wherein the plurality of fourth wires are arranged such that each of the plurality of fourth wires extends in a direction orthogonal to the direction along the vapor-phase flow path, and
wherein the fourth intervals are wider than the third intervals.

13. A heat-transporting device, comprising:
a working fluid to transport heat using a phase change;
a vessel to seal in the working fluid;
a vapor-phase flow path to cause the working fluid in a vapor phase to circulate inside the vessel; and
a liquid-phase flow path that includes a first mesh member and a second mesh member and causes the working fluid in a liquid phase to circulate inside the vessel, the first mesh member having a first mesh number, the second mesh member being laminated on the first mesh member and having a second mesh number different from the first mesh number.

14. The heat-transporting device according to claim 13,
wherein the first mesh number and the second mesh number are set so that a periodicity of the first mesh member and that of the second mesh member differ.

15. The heat-transporting device according to claim 13,
wherein the vapor-phase flow path includes a third mesh member.

16. An electronic apparatus, comprising:
a heat source; and
a heat-transporting device including
a working fluid to transport heat of the heat source using a phase change,
a vessel to seal in the working fluid,
a vapor-phase flow path to cause the working fluid in a vapor phase to circulate inside the vessel, and
a liquid-phase flow path that includes a laminated body and causes the working fluid in a liquid phase to circulate inside the vessel, the laminated body including a first mesh member and a second mesh member and being formed such that the first mesh member and the second mesh member are laminated while weaving directions thereof differ relatively.

17. An electronic apparatus, comprising:
a heat source; and
a heat-transporting device including
a working fluid to transport heat of the heat source using a phase change,
a vessel to seal in the working fluid,
a vapor-phase flow path to cause the working fluid in a vapor phase to circulate inside the vessel, and
a liquid-phase flow path that includes a mesh member and causes the working fluid in a liquid phase to circulate inside the vessel, the mesh member including a plurality of first wires that are arranged at first intervals and a plurality of second wires that are woven into the plurality of first wires and arranged at second intervals different from the first intervals.

18. An electronic apparatus, comprising:
a heat source; and
a heat-transporting device including
a working fluid to transport heat of the heat source using a phase change,
a vessel to seal in the working fluid,
a vapor-phase flow path to cause the working fluid in a vapor phase to circulate inside the vessel, and
a liquid-phase flow path that includes a first mesh member and a second mesh member and causes the working fluid in a liquid phase to circulate inside the vessel, the first mesh member having a first mesh number, the second mesh member being laminated on the first mesh member and having a second mesh number different from the first mesh number.

19. A method of producing a heat-transporting device, comprising:
bending a plate member such that a capillary member that causes a capillary force to act on a working fluid that transports heat using a phase change is sandwiched by the bent plate member; and
bonding the bent plate member.
